(19) United States
(12) Patent Application Publication
(10) Pub. No.: US 2025/0081577 A1
(43) Pub. Date: Mar. 6, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Masatsugu NAGAI, Nomi Ishikawa (JP); Hiroki HATADA, Kanazawa Ishikawa (JP)

(21) Appl. No.: 18/590,548

(22) Filed: Feb. 28, 2024

(30) Foreign Application Priority Data
Aug. 28, 2023 (JP) 2023-137670

(51) Int. Cl. H01L 29/41; H01L 29/04; H01L 29/739

(52) U.S. Cl. CPC H10D 64/20; H10D 62/40; H10D 12/441

(57) ABSTRACT

A semiconductor device of embodiments includes: a semiconductor layer including a first semiconductor region of a first conductive type, a second semiconductor region of a second conductive type, and a third semiconductor region of the first conductive type; and a gate electrode. The second semiconductor region includes first, second, and third regions. The gate electrode includes first, second, and third portions. The first, second, and third portions face the first, second, and third regions, respectively. The first portion, the second portion, and the third portion contain a first material, a second material, and a third material, respectively. When the first conductive type is n-type, the work function of the first material and the third material are smaller than that of the second material. When the first conductive type is p-type, the work function of the first material and the third material are larger than that of the second material.

### CROSS-REFERENCE TO RELATED APPLICATION

This application is based upon and claims the benefit of priority from Japanese Patent Application No. 2023-137670, filed on Aug. 28, 2023, the entire contents of which are incorporated herein by reference.

### FIELD

Embodiments described herein relate generally to a semiconductor device.

### BACKGROUND

In order to reduce the size of a transistor or improve the performance of a transistor, a vertical transistor is used in which a gate electrode is buried in a trench provided in a semiconductor layer. The vertical transistor is required to have reduced on-resistance.

### BRIEF DESCRIPTION OF THE DRAWINGS

FIG. 1 is a schematic top view of a semiconductor device according to a first embodiment;

FIG. 2 is a schematic top view of the semiconductor device according to the first embodiment;

FIG. 3 is a schematic cross-sectional view of the semiconductor device according to the first embodiment;

FIG. 4 is a schematic cross-sectional view of the semiconductor device according to the first embodiment;

FIG. 5 is a cross-sectional view showing an example of a method for manufacturing the semiconductor device according to the first embodiment;

FIG. 6 is a cross-sectional view showing an example of the method for manufacturing the semiconductor device according to the first embodiment;

FIG. 7 is a cross-sectional view showing an example of the method for manufacturing the semiconductor device according to the first embodiment;

FIG. 8 is a cross-sectional view showing an example of the method for manufacturing the semiconductor device according to the first embodiment;

FIG. 9 is a cross-sectional view showing an example of the method for manufacturing the semiconductor device according to the first embodiment;

FIG. 10 is a cross-sectional view showing an example of the method for manufacturing the semiconductor device according to the first embodiment;

FIG. 11 is a cross-sectional view showing an example of the method for manufacturing the semiconductor device according to the first embodiment;

FIG. 12 is a cross-sectional view showing an example of the method for manufacturing the semiconductor device according to the first embodiment;

FIG. 13 is a cross-sectional view showing an example of the method for manufacturing the semiconductor device according to the first embodiment;

FIG. 14 is a cross-sectional view showing an example of the method for manufacturing the semiconductor device according to the first embodiment;

FIG. 15 is a cross-sectional view showing an example of the method for manufacturing the semiconductor device according to the first embodiment;

FIG. 16 is a cross-sectional view showing an example of the method for manufacturing the semiconductor device according to the first embodiment;

FIG. 17 is a cross-sectional view showing an example of the method for manufacturing the semiconductor device according to the first embodiment;

FIG. 18 is a cross-sectional view showing an example of the method for manufacturing the semiconductor device according to the first embodiment;

FIG. 19 is a schematic cross-sectional view of a semiconductor device according to a comparative example;

FIG. 20 is a schematic cross-sectional view of a semiconductor device according to a third modification example of the first embodiment;

FIG. 21 is a schematic cross-sectional view of a semiconductor device according to a second embodiment;

FIG. 22 is a schematic cross-sectional view of a semiconductor device according to a third modification example of the second embodiment;

FIG. 23 is a schematic cross-sectional view of a semiconductor device according to a third embodiment;

FIG. 24 is a schematic cross-sectional view of the semiconductor device according to the third embodiment;

FIG. 25 is a schematic cross-sectional view of a semiconductor device according to a fourth embodiment;

FIG. 26 is a schematic cross-sectional view of a semiconductor device according to a fifth embodiment;

FIG. 27 is a schematic cross-sectional view of a semiconductor device according to a second modification example of the fifth embodiment;

FIG. 28 is a schematic cross-sectional view of a semiconductor device according to a sixth embodiment; and

FIG. 29 is a schematic cross-sectional view of a semiconductor device according to a second modification example of the sixth embodiment.

### DETAILED DESCRIPTION

A semiconductor device of embodiments includes: a semiconductor layer having a first face and a second face opposite to the first face, the semiconductor layer including a first semiconductor region of a first conductive type, a second semiconductor region of a second conductive type provided between the first semiconductor region and the first face, and a third semiconductor region of the first conductive type provided between the second semiconductor region and the first face; a first electrode provided on the first face side of the semiconductor layer and electrically connected to the third semiconductor region; a second electrode provided on the second face side of the semiconductor layer; a gate electrode provided in the semiconductor layer and facing the first semiconductor region, the second semiconductor region, and the third semiconductor region; and a gate insulating layer provided between the gate electrode and the first semiconductor region, between the gate electrode and the second semiconductor region, and between the gate electrode and the third semiconductor region. The second semiconductor region includes a first region, a second region, and a third region. The first region is provided between the second region and the first semiconductor region, and the third region is provided between the second region and the third semiconductor region. The gate electrode includes a first portion, a second portion, and a third portion. The first portion faces the first region, the second portion faces the second region, the third portion faces the third region. The first portion contains a first material, the second portion contains a second material, and the third portion contains a third material. When the first conductive type is n-type and the second conductive type is p-type, a work function of the first material and a work function of the third material are smaller than a work function of the second material. When the first conductive type is p-type and the second conductive type is n-type, the work function of the first material and the work function of the third material are larger than the work function of the second material.

Hereinafter, embodiments will be described with reference to the diagrams. In the following description, the same or similar members and the like will be denoted by the same reference numerals, and the description of the members and the like once described will be omitted as appropriate.

In addition, in the following description, when the notations of n⁺, n, n⁻, p⁺, p, and p⁻ are used, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentration in a semiconductor device can be measured by, for example, secondary ion mass spectrometry (SIMS). In addition, the relative high and low of the impurity concentration in the semiconductor device can be determined from, for example, the high and low of the carrier concentration obtained by scanning capacitance microscopy (SCM). In addition, the distance such as the width or depth of an impurity region in the semiconductor device can be calculated by, for example, SIMS. In addition, the distance such as the width or depth of an impurity region in the semiconductor device can be calculated from, for example, an SCM image.

The depth of a trench, the thickness of an insulating layer, and the like of a semiconductor device can be measured, for example, on an image of a transmission electron microscope (TEM).

The materials of members forming the semiconductor device can be identified by using, for example, energy dispersive X-ray spectroscopy (EDX).

### First Embodiment

A semiconductor device according to a first embodiment includes: a semiconductor layer having a first face and a second face opposite to the first face, the semiconductor layer including a first semiconductor region of a first conductive type, a second semiconductor region of a second conductive type provided between the first semiconductor region and the first face, and a third semiconductor region of the first conductive type provided between the second semiconductor region and the first face; a first electrode provided on the first face side of the semiconductor layer and electrically connected to the third semiconductor region; a second electrode provided on the second face side of the semiconductor layer; a gate electrode provided in the semiconductor layer and facing the first semiconductor region, the second semiconductor region, and the third semiconductor region; and a gate insulating layer provided between the gate electrode and the first semiconductor region, between the gate electrode and the second semiconductor region, and between the gate electrode and the third semiconductor region. The second semiconductor region includes a first region, a second region, and a third region. The first region is provided between the second region and the first semiconductor region, and the third region is provided between the second region and the third semiconductor region. The gate electrode includes a first portion, a second portion, and a third portion. The first portion faces the first region, the second portion faces the second region, the third portion faces the third region. The first portion contains a first material, the second portion contains a second material, and the third portion contains a third material. When the first conductive type is n-type and the second conductive type is p-type, a work function of the first material and a work function of the third material are smaller than a work function of the second material. When the first conductive type is p-type and the second conductive type is n-type, the work function of the first material and the work function of the third material are larger than the work function of the second material.

The semiconductor device according to the first embodiment is a vertical transistor in which a gate electrode is buried in a trench. The semiconductor device according to the first embodiment is a vertical power metal oxide semiconductor field effect transistor (MOSFET). The semiconductor device according to the first embodiment is a MOSFET 100. The trench in this specification is a groove-shaped or concave structure that the semiconductor layer itself has, and a structure other than the semiconductor layer can be provided thereinside.

Hereinafter, a case where the first conductive type is n-type and the second conductive type is p-type will be described. That is, the case of an n-channel MOSFET using electrons as carriers will be described.

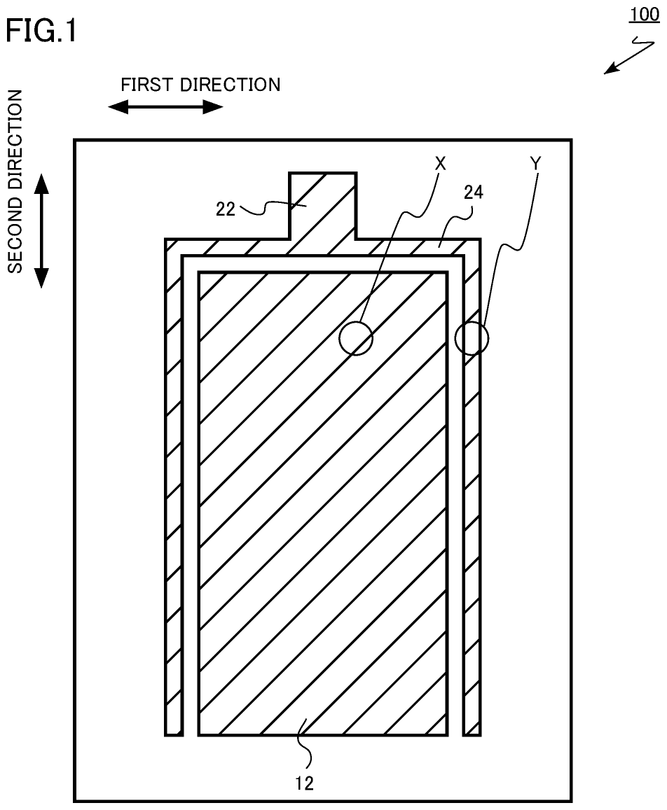

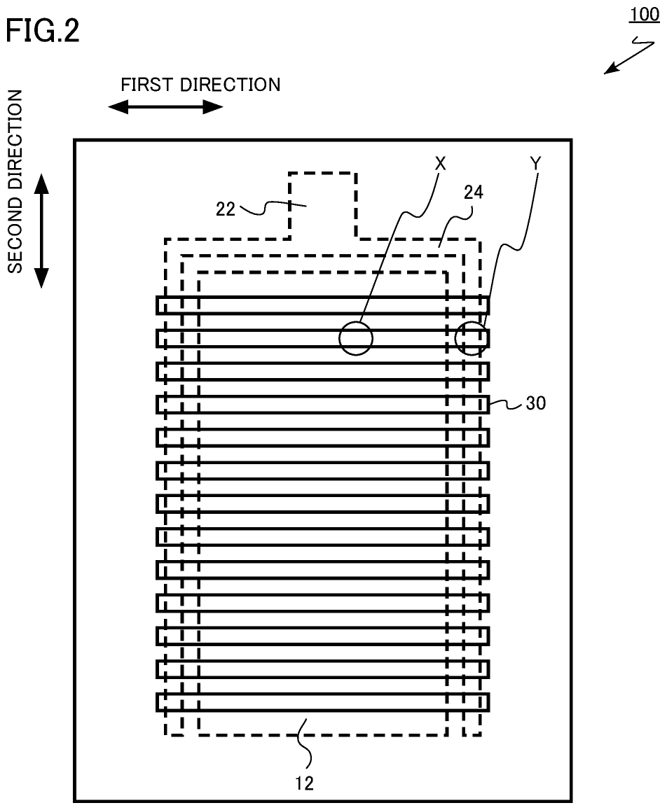

FIGS. 1 and 2 are schematic top views of the semiconductor device according to the first embodiment. FIG. 1 is a top view showing a layout pattern of electrodes and wiring of the MOSFET 100. FIG. 2 is a top view showing a trench layout pattern of the MOSFET 100. In FIG. 2, the layout pattern of electrodes and wiring is shown by dotted lines.

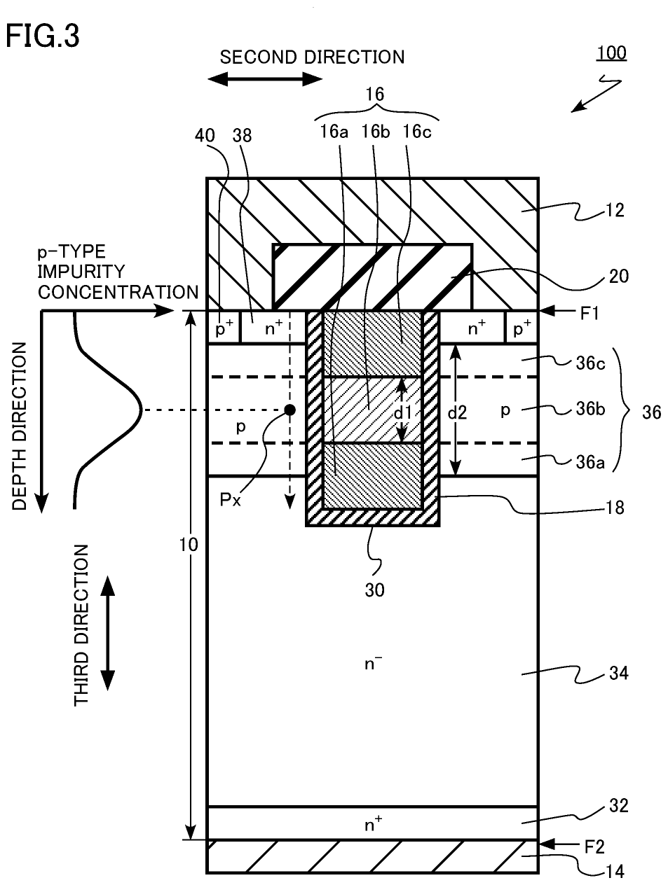

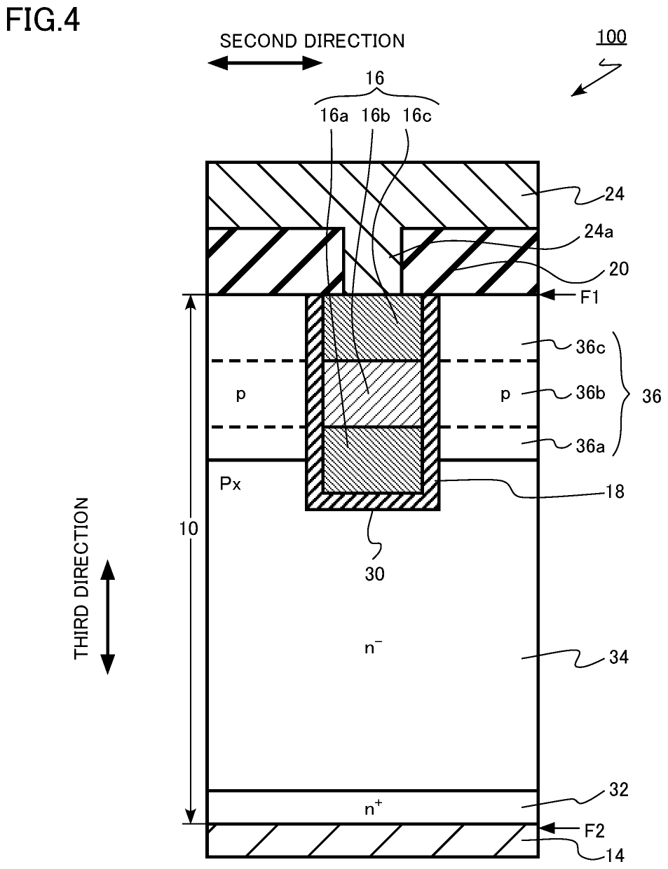

FIGS. 3 and 4 are schematic cross-sectional views of the semiconductor device according to the first embodiment. FIG. 3 is a cross section of a region X shown in FIGS. 1 and 2. In addition, FIG. 4 is a cross section of a region Y shown in FIGS. 1 and 2. FIG. 3 shows the impurity concentration distribution in a part of the semiconductor layer.

In FIGS. 1 and 2, the horizontal direction is defined as a first direction, and the vertical direction is defined as a second direction. FIGS. 3 and 4 are cross sections perpendicular to the first direction. In FIGS. 3 and 4, the vertical direction is defined as a third direction.

The MOSFET 100 includes a silicon layer 10, a source electrode 12, a drain electrode 14, a gate electrode 16, a gate insulating layer 18, an interlayer insulating layer 20, a gate electrode pad 22, and a gate wiring 24.

The silicon layer 10 is an example of the semiconductor layer. The source electrode 12 is an example of the first electrode. The drain electrode 14 is an example of the second electrode.

The gate electrode 16 has a first portion 16a, a second portion 16b, and a third portion 16c. The gate wiring 24 includes a contact portion 24a.

The silicon layer 10 includes a trench 30, an n⁺-type drain region 32, an n⁻-type drift region 34, a p-type body region 36, an n⁺-type source region 38, and a p⁺-type contact region 40.

The drift region 34 is an example of the first semiconductor region. The body region 36 is an example of the second semiconductor region. The source region 38 is an example of the third semiconductor region.

The body region 36 includes a first region 36a, a second region 36b, and a third region 36c.

The silicon layer 10 is disposed between the source electrode 12 and the drain electrode 14. The silicon layer 10 has a first face (“F1” in FIG. 3) and a second face (“F2” in FIG. 3). The second face F2 is opposite to the first face F1.

The first direction and the second direction are directions parallel to the first face F1. In addition, the second direction is a direction crossing the first direction. The second direction is a direction perpendicular to the first direction. In addition, the third direction is a direction perpendicular to the first face F1. The third direction is a direction perpendicular to the first direction and the second direction. The third direction is a direction from the source electrode 12 to the drain electrode 14.

Hereinafter, “depth” means a depth with respect to the first face F1. That is, “depth” means a distance in the third direction with respect to the first face F1.

The silicon layer 10 is single crystal silicon (Si). The surface of the silicon layer 10 is, for example, a surface inclined at an angle equal to or more than 0° and equal to or less than 8° with respect to the (100) face.

The n⁺-type drain region 32 is provided in the silicon layer 10. The drain region 32 contains n-type impurities. The n-type impurity is, for example, phosphorus (P) or arsenic (As). The n-type impurity concentration in the drain region 32 is, for example, equal to or more than 1×10¹⁸ cm⁻³ and equal to or less than 1×10²¹ cm⁻³.

The n⁻-type drift region 34 is provided in the silicon layer 10. The drift region 34 is provided between the drain region 32 and the first face F1. The drift region 34 is provided on the drain region 32.

The drift region 34 contains n-type impurities. The n-type impurity is, for example, phosphorus (P) or arsenic (As). The n-type impurity concentration in the drift region 34 is, for example, equal to or more than 1×10¹⁵ cm⁻³ and equal to or less than 1×10¹⁸ cm⁻³. The drift region 34 is, for example, an epitaxial growth layer formed on the n⁺-type drain region 32 by epitaxial growth.

The thickness of the drift region 34 in the third direction is, for example, equal to or more than 5 μm and equal to or less than 20 μm.

The p-type body region 36 is provided in the silicon layer 10. The body region 36 is provided between the drift region 34 and the first face F1. When the MOSFET 100 is turned on, a channel is formed in a region of the body region 36 along the gate insulating layer 18.

The body region 36 includes the first region 36a, the second region 36b, and the third region 36c. The first region 36a is provided between the second region 36b and the drift region 34. The third region 36c is provided between the second region 36b and the source region 38.

The body region 36 contains p-type impurities. The p-type impurity is, for example, boron (B). The p-type impurity concentration in the body region 36 is, for example, equal to or more than 1×10¹⁶ cm⁻³ and equal to or less than 1×10¹⁸ cm⁻³.

The p-type impurity concentration in the second region 36b is higher than the p-type impurity concentration in the first region 36a. The p-type impurity concentration in the second region 36b is higher than the p-type impurity concentration in the third region 36c.

As shown in FIG. 3, the p-type impurity concentration in the depth direction in a region of the body region 36 along the gate insulating layer 18 is maximum at a position Px. The position Px is in the second region 36b. The p-type impurity concentration distribution in the depth direction in the region of the body region 36 along the gate insulating layer 18 has a maximum peak in the second region 36b.

The n⁺-type source region 38 is provided in the silicon layer 10. The source region 38 is provided between the body region 36 and the first face F1.

The source region 38 contains n-type impurities. The n-type impurity is, for example, phosphorus (P) or arsenic (As). The n-type impurity concentration in the source region 38 is, for example, equal to or more than 1×10¹⁹ cm⁻³ and equal to or less than 1×10²¹ cm⁻³.

The p⁺-type contact region 40 is provided in the silicon layer 10. The contact region 40 is provided between the body region 36 and the first face F1.

The contact region 40 contains p-type impurities. The p-type impurity is, for example, boron (B). The p-type impurity concentration in the contact region 40 is, for example, equal to or more than 1×10¹⁹ cm⁻³ and equal to or less than 1×10²¹ cm⁻³. The p-type impurity concentration in the contact region 40 is higher than the p-type impurity concentration in the body region 36.

The trench 30 is present in the silicon layer 10. The trench 30 is disposed on the first face F1 side of the silicon layer 10. The trench 30 is a groove formed in the silicon layer 10.

The trench 30 passes through the source region 38 and the body region 36 to reach the drift region 34. The depth of the trench 30 is, for example, equal to or more than 0.5 μm and equal to or less than 5 μm.

The trench 30 extends in the first direction on the first face F1, as shown in FIG. 2. The trenches 30 are repeatedly arranged at predetermined pitches in the second direction.

The gate electrode 16 is provided in the silicon layer 10. The gate electrode 16 is provided in the trench 30. The gate electrode 16 is provided in the middle of the body region 36 in the second direction. The gate electrode 16 extends in the first direction.

The gate electrode 16 has a first portion 16a, a second portion 16b, and a third portion 16c. The second portion 16b is provided between the first portion 16a and the third portion 16c. The first portion 16a is provided on the second face F2 side with respect to the second portion 16b. The third portion 16c is provided on the first face F1 side with respect to the second portion 16b.

The second portion 16b is in contact with the first portion 16a and the third portion 16c. The first portion 16a, the second portion 16b, and the third portion 16c are electrically connected to each other.

The first portion 16a faces the first region 36a of the body region 36 in the second direction. The second portion 16b faces the second region 36b of the body region 36 in the second direction. The third portion 16c faces the third region 36c of the body region 36 in the second direction.

The first portion 16a contains a first material. The second portion 16b contains a second material. Third portion 16c contains a third material.

The first portion 16a is formed of, for example, a first material. The second portion 16b is formed of, for example, a second material. The third portion 16c is formed of, for example, a third material.

The work function of the first material is smaller than the work function of the second material. The work function of the third material is smaller than the work function of the second material.

The work function is the energy difference between the Fermi level and the vacuum level. By specifying the first material, the second material, and the third material, the work function of each of these materials can be specified.

The difference between the work function of the first material and the work function of the second material is, for example, equal to or more than 0.2 eV and equal to or less than 4.0 eV. In addition, the difference between the work function of the third material and the work function of the second material is, for example, equal to or more than 0.2 eV and equal to or less than 4.0 eV.

The first material, the second material, and the third material are n-type polycrystalline silicon containing n-type impurities. The n-type impurity concentration of the first material is higher than the n-type impurity concentration of the second material. The n-type impurity concentration of the third material is higher than the n-type impurity concentration of the second material.

In n-type polycrystalline silicon, the higher the n-type impurity concentration, the smaller the energy difference between the Fermi level and the bottom of the conduction band, and the smaller the work function.

The length (d1 in FIG. 3) of the second portion 16b in the third direction is, for example, equal to or more than 20% and equal to or less than 70% of the length (d2 in FIG. 3) between the drift region 34 and the source region 38 in the third direction.

As shown in FIG. 3, the position Px where the p-type impurity concentration in the depth direction in a region of the body region 36 along the gate insulating layer 18 is maximum faces the second portion 16b in the second direction, for example.

The gate insulating layer 18 is provided in the trench 30. The gate insulating layer 18 is provided between the gate electrode 16 and the silicon layer 10. The gate insulating layer 18 is provided between the gate electrode 16 and the body region 36. The gate insulating layer 18 is provided between the gate electrode 16 and the drift region 34. The gate insulating layer 18 is provided between the gate electrode 16 and the source region 38. The gate insulating layer 18 is, for example, a silicon oxide.

The interlayer insulating layer 20 is provided on the silicon layer 10. The interlayer insulating layer 20 is provided between the gate electrode 16 and the source electrode 12. The interlayer insulating layer 20 has a function of electrically separating the gate electrode 16 and the source electrode 12 from each other.

The interlayer insulating layer 20 is, for example, a silicon oxide.

The source electrode 12 is provided on the first face F1 side of the silicon layer 10. The source electrode 12 is provided on the first face F1 of the silicon layer 10.

The source electrode 12 is electrically connected to the source region 38 and the contact region 40. The source electrode 12 is in contact with the source region 38 and the contact region 40, for example.

The source electrode 12 is a region to which, for example, a bonding wire is connected when the MOSFET 100 is mounted.

The source electrode 12 is a metal electrode. The source electrode 12 has, for example, a stacked structure of titanium (Ti) and aluminum (Al).

The drain electrode 14 is provided on the second face F2 side of the silicon layer 10. The drain electrode 14 is provided on the second face F2 of the silicon layer 10. The drain electrode 14 is electrically connected to the drain region 32. The drain electrode 14 is in contact with, for example, the drain region 32.

The drain electrode 14 is a metal electrode. The drain electrode 14 has a stacked structure of materials selected from, for example, titanium (Ti), aluminum (Al), nickel (Ni), copper (Cu), silver (Ag), and gold (Au).

The gate electrode pad 22 is provided on the first face F1 side of the silicon layer 10. The gate electrode pad 22 is provided on the first face F1 of the silicon layer 10.

The gate electrode pad 22 is electrically connected to the gate electrode 16. The gate electrode pad 22 is a region to which, for example, a bonding wire is connected when the MOSFET 100 is mounted.

The gate electrode pad 22 is a metal electrode. The gate electrode pad 22 has, for example, a stacked structure of titanium (Ti) and aluminum (Al). The material of the gate electrode pad 22 is the same as the material of the source electrode 12, for example.

The gate wiring 24 is provided at the end of the source electrode 12 as shown in FIG. 1. The gate wiring 24 is electrically connected to the gate electrode 16.

The gate wiring 24 is a metal wiring. The gate wiring 24 has, for example, a stacked structure of titanium (Ti) and aluminum (Al). The material of the gate wiring 24 is the same as the material of the source electrode 12 and the material of the gate electrode pad 22, for example.

As shown in FIG. 4, the gate wiring 24 is connected to the gate electrode 16 in the region Y. The contact portion 24a of the gate wiring 24 is connected to the gate electrode 16 in the region Y. For example, the contact portion 24a passes through the interlayer insulating layer 20 to be connected to the gate electrode 16.

The contact portion 24a is in contact with, for example, the third portion 16c of the gate electrode 16. For example, the contact portion 24a is electrically and physically connected to the third portion 16c of the gate electrode 16.

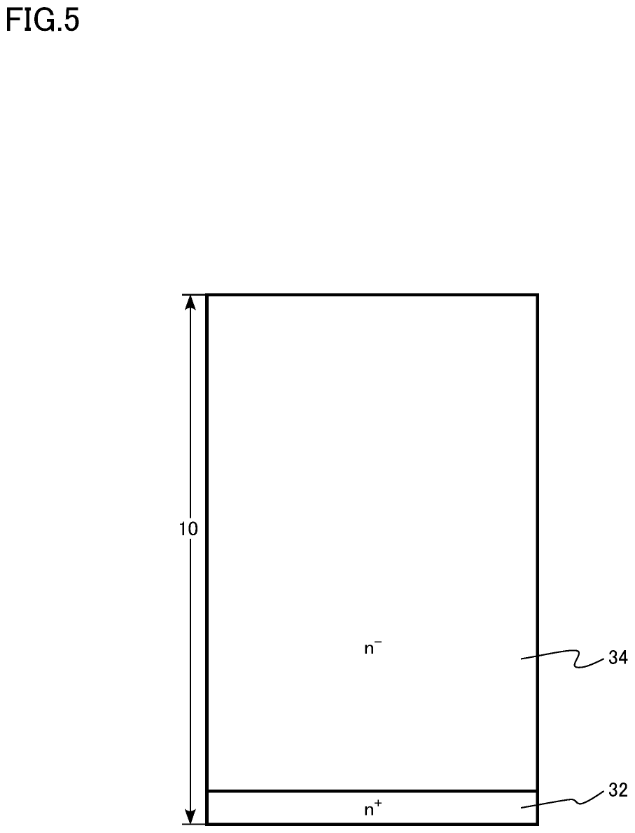

Next, an example of a method for manufacturing the semiconductor device according to the first embodiment will be described. FIGS. 5 to 18 are cross-sectional views showing an example of the method for manufacturing the semiconductor device according to the first embodiment.

FIGS. 5 to 18 are cross sections of the region X in FIGS. 1 and 2. FIGS. 5 to 18 are cross sections corresponding to FIG. 3.

First, the silicon layer 10 is prepared (FIG. 5). The silicon layer 10 includes the n⁺-type drain region 32 and the n⁻-type drift region 34.

The drift region 34 is formed on the drain region 32 by using, for example, an epitaxial growth method.

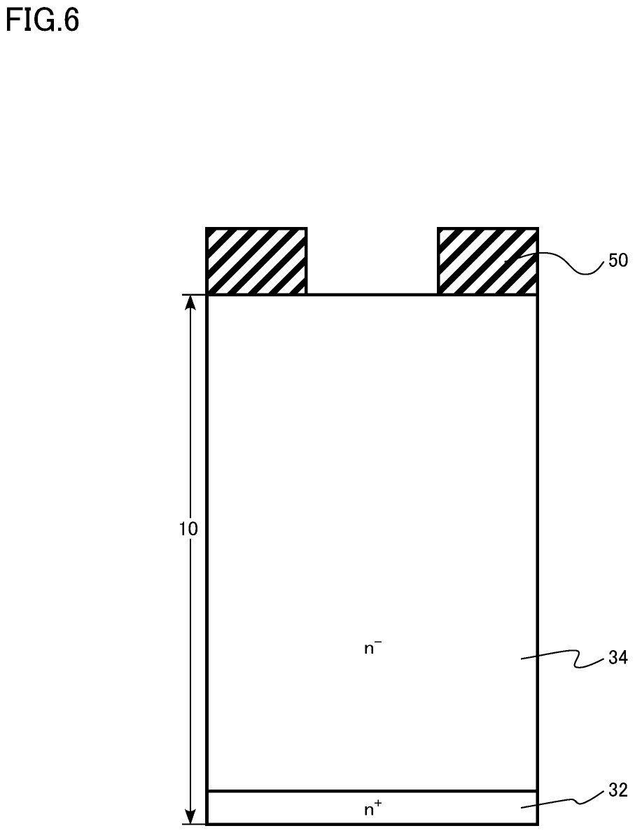

Then, a mask material 50 is formed on the silicon layer 10 (FIG. 6). The mask material 50 is formed by using, for example, a chemical vapor deposition method (CVD method), a photolithography method, and a reactive ion etching method (RIE method). The mask material 50 is, for example, a silicon nitride or a silicon oxide.

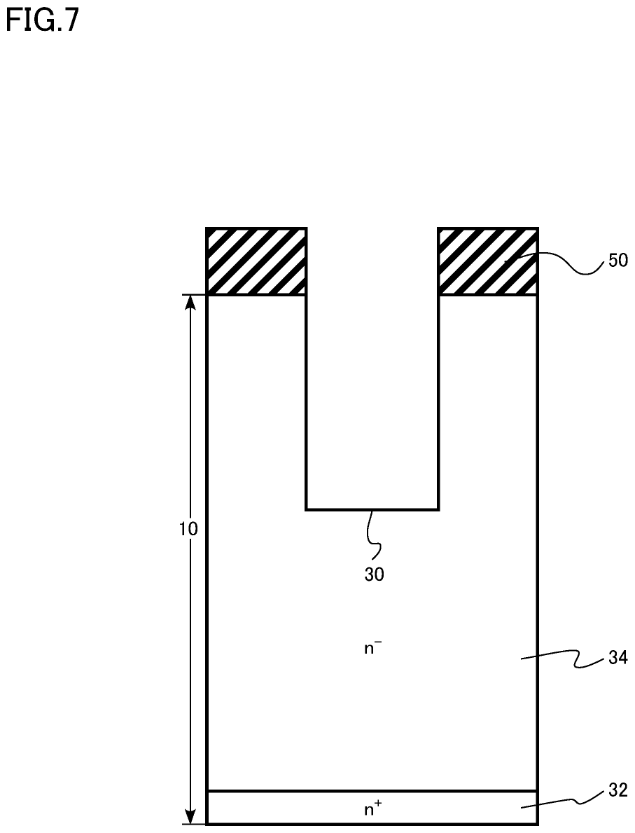

Then, the trench 30 is formed by using the mask material 50 as a mask (FIG. 7). The trench 30 is formed by using, for example, an RIE method.

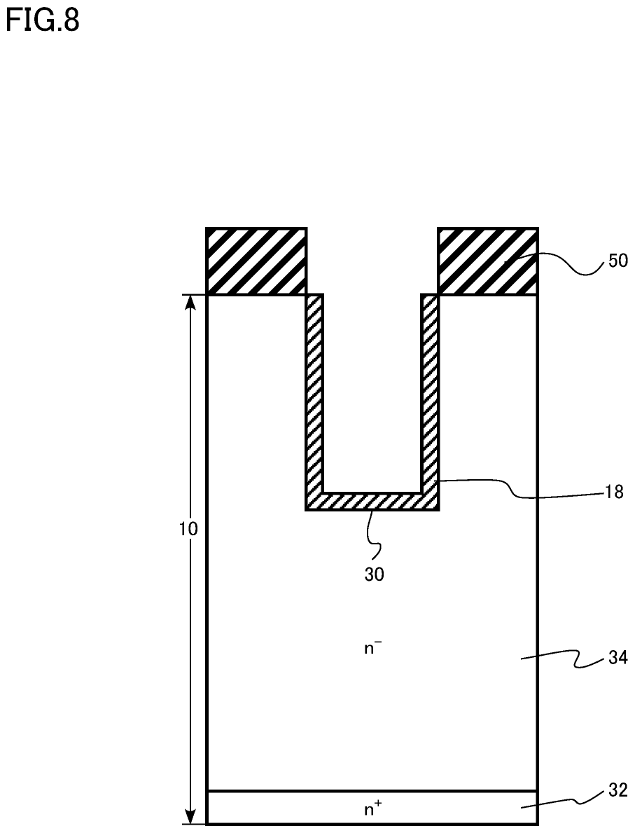

Then, the gate insulating layer 18 is formed on the inner wall of the trench 30 (FIG. 8). The gate insulating layer 18 is formed, for example, by thermal oxidation.

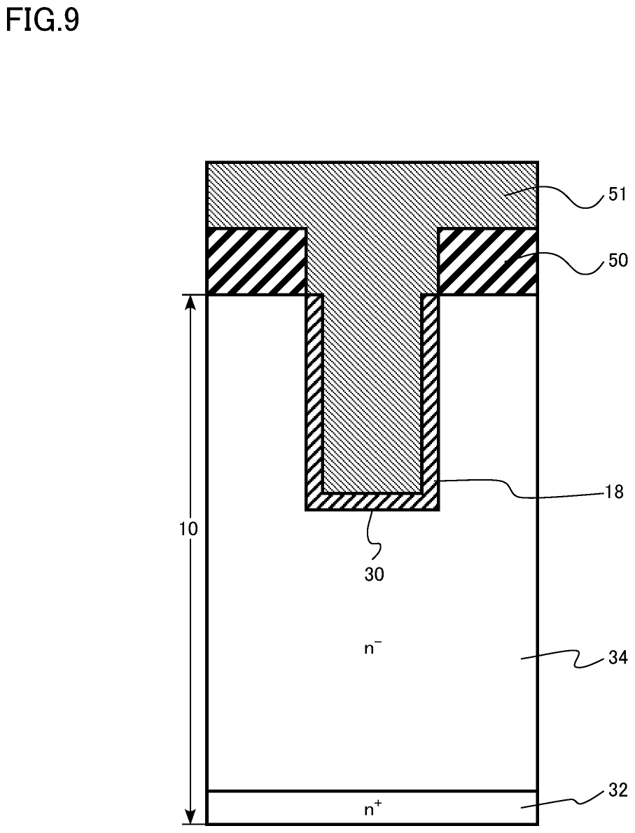

Then, the trench 30 is filled with a first polycrystalline silicon 51 of n-type (FIG. 9). The first polycrystalline silicon 51 is formed by using, for example, a CVD method.

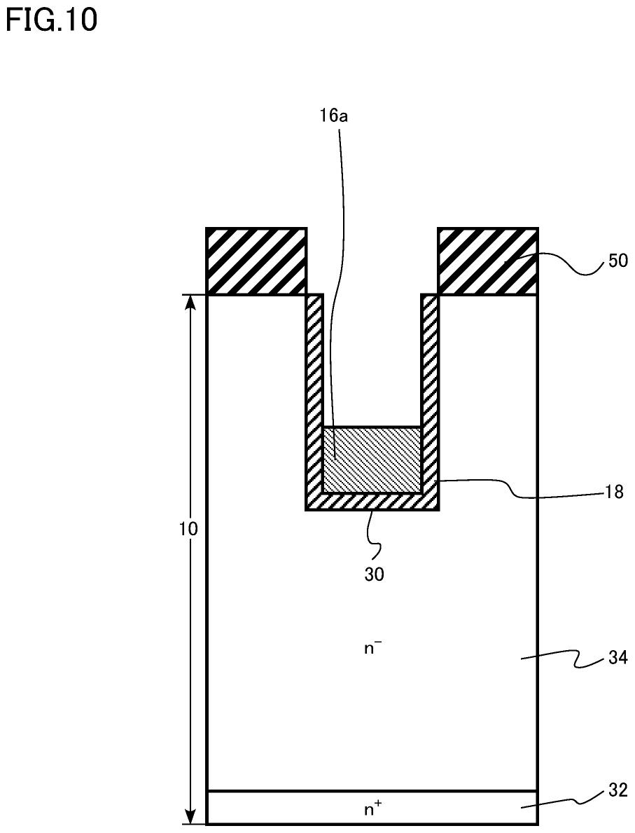

Then, the first polycrystalline silicon 51 is etched to form the first portion 16a of the gate electrode 16 (FIG. 10). The first portion 16a is formed by using, for example, an RIE method.

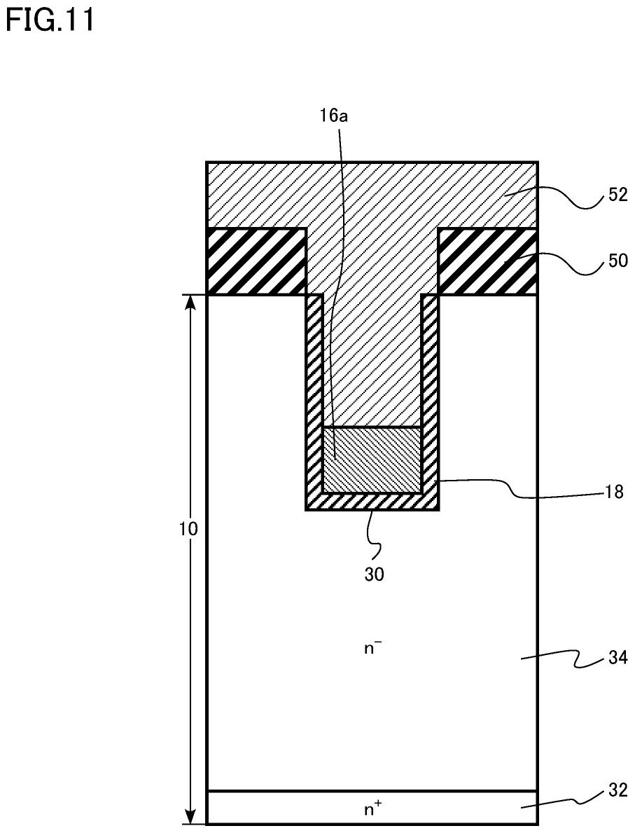

Then, the trench 30 is filled with a second polycrystalline silicon 52 of n-type (FIG. 11). The second polycrystalline silicon 52 is formed by using, for example, a CVD method. The n-type impurity concentration in the second polycrystalline silicon 52 is lower than the n-type impurity concentration in the first polycrystalline silicon 51.

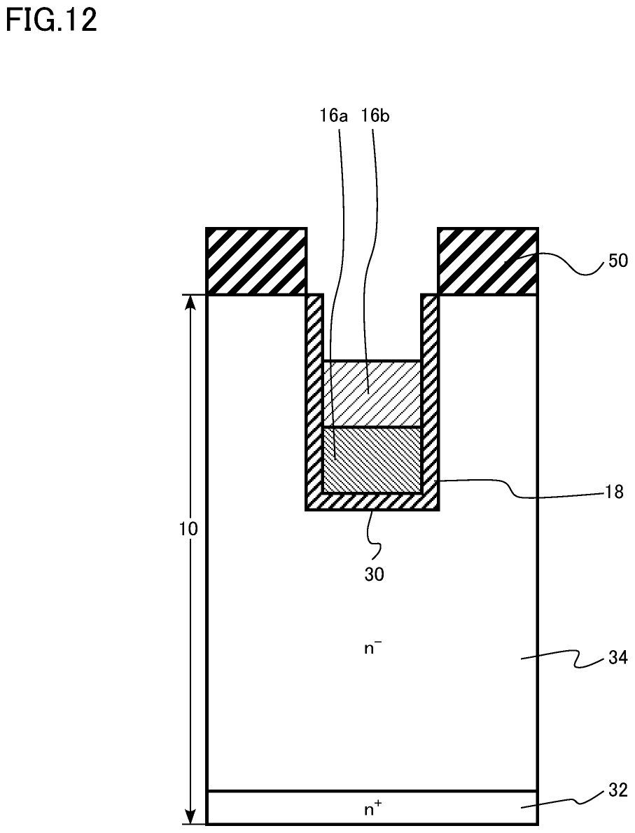

Then, the second polycrystalline silicon 52 is etched to form the second portion 16b of the gate electrode 16 (FIG. 12). The second portion 16b is formed by using, for example, an RIE method.

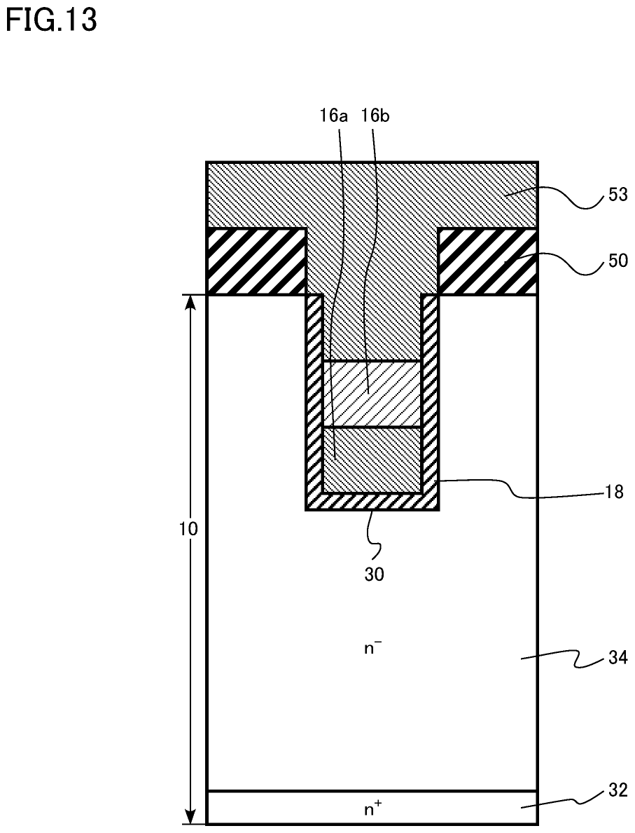

Then, the trench 30 is filled with a third polycrystalline silicon 53 of n-type (FIG. 13). The third polycrystalline silicon 53 is formed by using, for example, a CVD method. The n-type impurity concentration in the third polycrystalline silicon 53 is higher than the n-type impurity concentration in the second polycrystalline silicon 52.

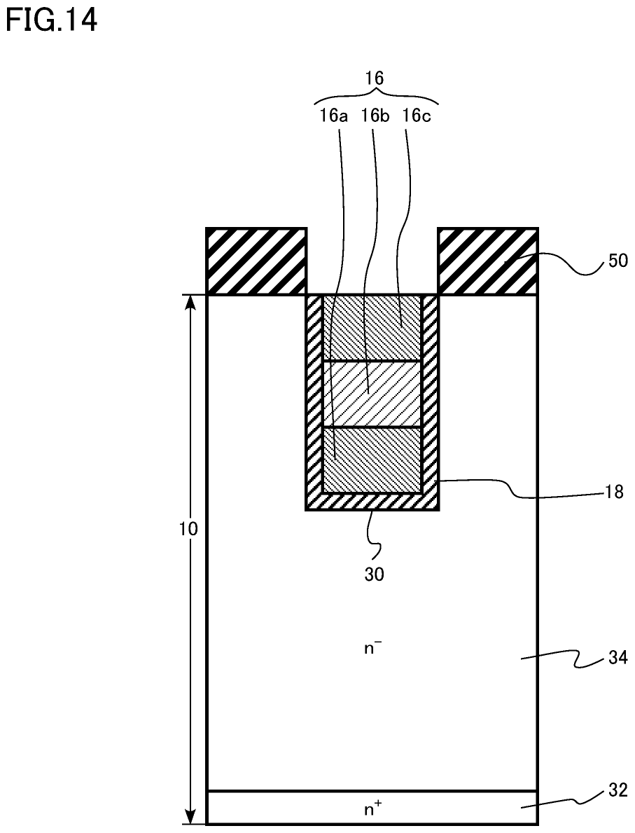

Then, the third polycrystalline silicon 53 is etched to form the third portion 16c of the gate electrode 16 (FIG. 14). The third portion 16c is formed by using, for example, an RIE method.

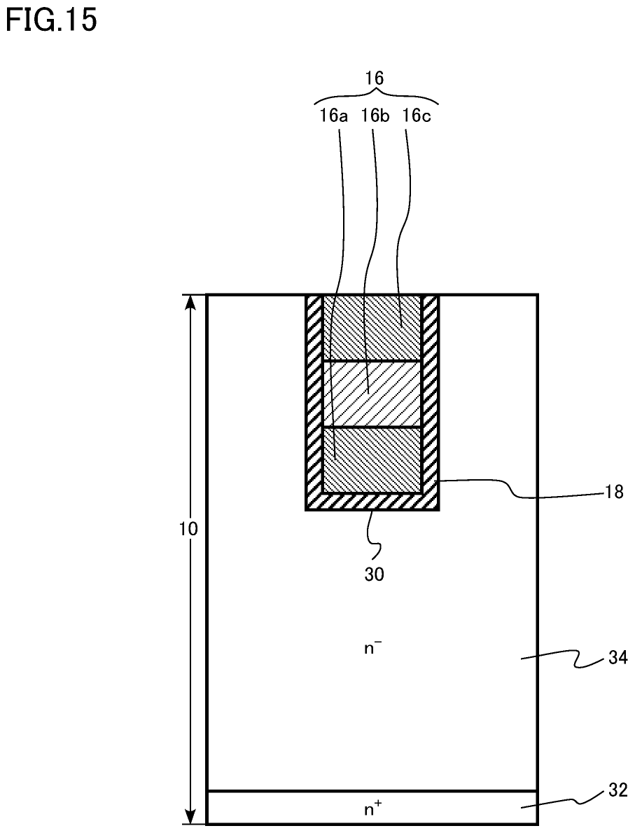

Then, the mask material 50 is removed (FIG. 15). The mask material 50 is removed by using, for example, a wet etching method.

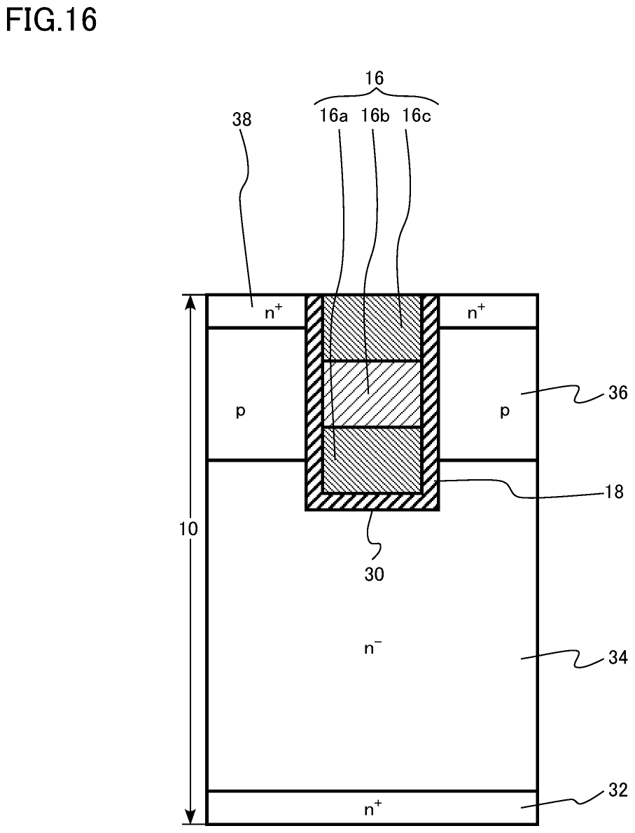

Then, the p-type body region 36 and the n⁺-type source region 38 are formed in the silicon layer 10 (FIG. 16). The body region 36 and the source region 38 are formed by using an ion implantation method.

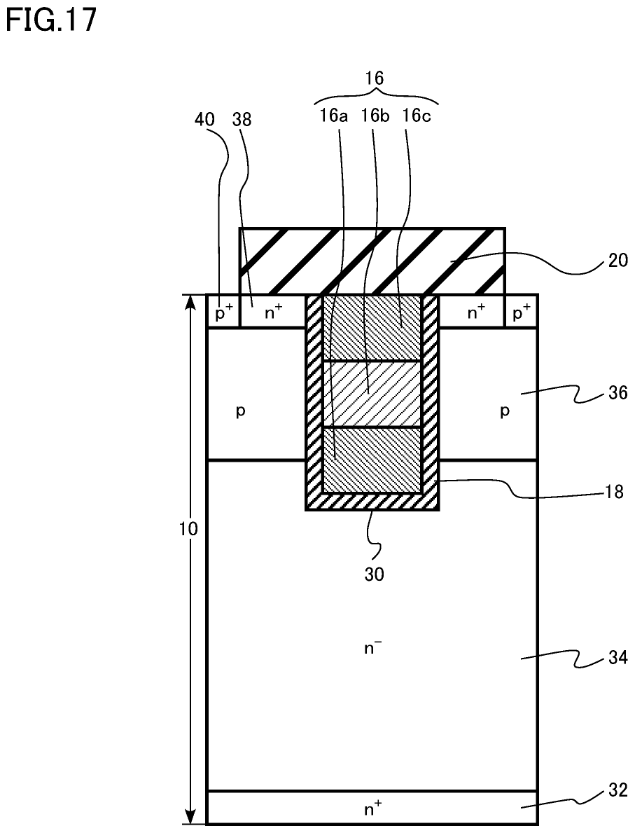

Then, the interlayer insulating layer 20 having an opening is formed on the silicon layer 10 (FIG. 17). The interlayer insulating layer 20 is formed by using, for example, a CVD method, a photolithography method, or an RIE method.

Then, the p⁺-type contact region 40 is formed in the silicon layer 10. For example, the contact region 40 is formed by using an ion implantation method in which the interlayer insulating layer 20 having an opening is used as a mask material.

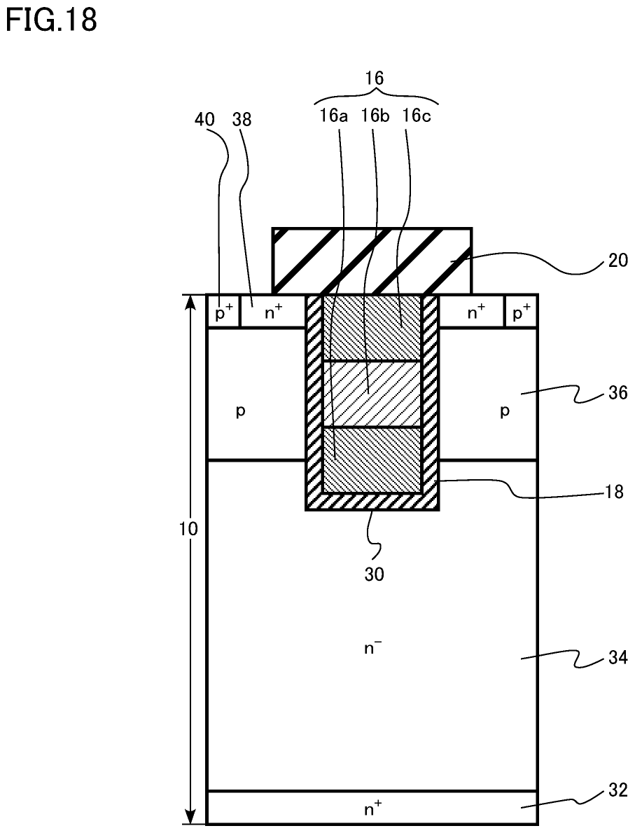

Then, the opening in the interlayer insulating layer 20 is widened horizontally to expose the n⁺-type source region 38 (FIG. 18). The opening in the interlayer insulating layer 20 is widened horizontally by using, for example, a wet etching method.

Thereafter, the source electrode 12, the gate electrode pad 22, the gate wiring 24, and the drain electrode 14 are formed by using a known manufacturing method.

By using the manufacturing method described above, the MOSFET 100 according to the first embodiment is manufactured.

Hereinafter, the function and effect of the semiconductor device according to the first embodiment will be described.

In order to reduce the size of a transistor or improve the performance of a transistor, a vertical transistor is used in which a gate electrode is buried in a trench provided in a semiconductor layer. The vertical transistor is required to have reduced on-resistance.

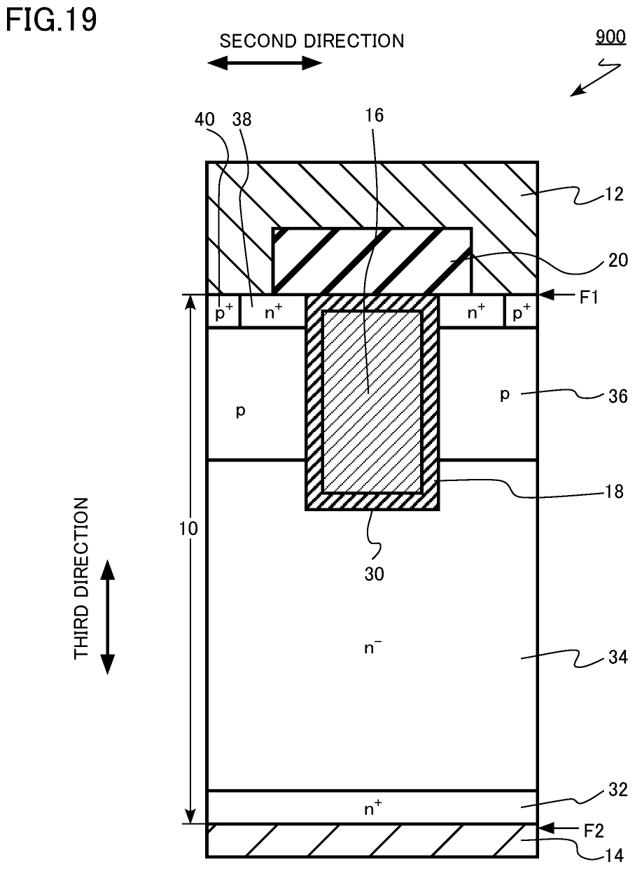

FIG. 19 is a schematic cross-sectional view of a semiconductor device according to a comparative example. The semiconductor device according to the comparative example is a MOSFET 900. FIG. 19 is a diagram corresponding to FIG. 3 in the first embodiment.

The MOSFET 900 is different from the MOSFET 100 according to the first embodiment in that the gate electrode 16 does not include the first portion 16a, the second portion 16b, and the third portion 16c.

The on-resistance of the MOSFET 900 includes the channel resistance or the resistance of the drift region 34. For example, particularly in a MOSFET used for low breakdown voltage applications, the resistance of the drift region 34 is low because the thickness of the drift region 34 is small. For this reason, particularly in the MOSFET used for low breakdown voltage applications, the proportion of the channel resistance in the on-resistance increases.

In order to reduce the channel resistance of the MOSFET 900, it is conceivable to lower the threshold voltage of the MOSFET 900, for example. By lowering the threshold voltage of the MOSFET 900 the electron density in the inversion layer when the MOSFET 900 is ON increases to reduce the channel resistance.

However, if the threshold voltage of the MOSFET 900 is lowered, there is a problem that the MOSFET 900 is unexpectedly turned on when the MOSFET 900 is OFF or the leakage current when the MOSFET 900 is OFF increases.

In the MOSFET 100 according to the first embodiment, the gate electrode 16 includes the first portion 16a, the second portion 16b, and the third portion 16c. The work function of the first material contained in the first portion 16a is smaller than the work function of the second material contained in the second portion 16b. In addition, the work function of the third material contained in the third portion 16c is smaller than the work function of the second material contained in the second portion 16b.

Since the work function of the first material is smaller than the work function of the second material, the threshold voltage of the MOSFET formed by the first portion 16a, the gate insulating layer 18, and the first region 36a is lower than the threshold voltage of the MOSFET formed by the second portion 16b, the gate insulating layer 18, and the second region 36b. In other words, the threshold voltage of the MOSFET having the first portion 16a as its gate electrode is lower than the threshold voltage of the MOSFET having the second portion 16b as its gate electrode.

Similarly, since the work function of the third material is smaller than the work function of the second material, the threshold voltage of the MOSFET formed by the third portion 16c, the gate insulating layer 18, and the third region 36c is lower than the threshold voltage of the MOSFET formed by the second portion 16b, the gate insulating layer 18, and the second region 36b. In other words, the threshold voltage of the MOSFET having the third portion 16c as its gate electrode is lower than the threshold voltage of the MOSFET having the second portion 16b as its gate electrode.

In the MOSFET 100 according to the first embodiment, since the threshold voltage of the MOSFET having the first portion 16a as its gate electrode and the threshold voltage of the MOSFET having the third portion 16c as its gate electrode are low, the channel resistance of the channel formed in the first region 36a and the channel resistance of the channel formed in the third region 36c are reduced. Therefore, the on-resistance of the MOSFET 100 is reduced.

On the other hand, since the threshold voltage of the MOSFET having the second portion 16b as its gate electrode is kept relatively high, the threshold voltage of the MOSFET 100 can be kept high.

For example, as shown in FIG. 3, a case is considered in which the p-type impurity concentration distribution in the depth direction in a region of the body region 36 along the gate insulating layer 18 has a maximum peak in the second region 36b. In this case, it is preferable that the position Px where the p-type impurity concentration is maximum faces the second portion 16b in the second direction. Since the position Px where the p-type impurity concentration is maximum faces the second portion 16b, the threshold voltage of the MOSFET having the second portion 16b as its gate electrode can be further increased.

From the viewpoint of reducing the on-resistance of the MOSFET 100, the difference between the work function of the first material and the work function of the second material is preferably equal to or more than 0.2 eV, more preferably equal to or more than 0.5 eV, and even more preferably equal to or more than 1.0 eV, for example.

Similarly, from the viewpoint of reducing the on-resistance of the MOSFET 100, the difference between the work function of the third material and the work function of the second material is preferably equal to or more than 0.2 eV, more preferably equal to or more than 0.5 eV, and even more preferably equal to or more than 1.0 eV, for example.

The length (d1 in FIG. 3) of the second portion 16b in the third direction is preferably equal to or more than 20% and equal to or less than 70% of the length (d2 in FIG. 3) between the drift region 34 and the source region 38 in the third direction, more preferably equal to or more than 30% and equal to or less than 60%, and even more preferably equal to or more than 40% and equal to or less than 50%, for example. By making the length (d1 in FIG. 3) of the second portion 16b in the third direction exceed the lower limit value described above, a decrease in threshold voltage can be suppressed. In addition, by making the length (d1 in FIG. 3) of the second portion 16b in the third direction less than the upper limit value described above, the on-resistance is further reduced.

As described above, according to the MOSFET 100 according to the first embodiment, it is possible to reduce the on-resistance.

### First Modification Example

A semiconductor device according to a first modification example of the first embodiment is different from the semiconductor device according to the first embodiment in that the second material is p-type polycrystalline silicon.

In a MOSFET according to the first modification example of the first embodiment, the second material contained in the second portion 16b of the gate electrode 16 is p-type polycrystalline silicon. The first material contained in the first portion 16a of the gate electrode 16 and the third material contained in the third portion 16c of the gate electrode 16 are n-type polycrystalline silicon.

Since the p-type polycrystalline silicon is used as the second material, the work function of the second material is larger than that when the second material is n-type polycrystalline silicon. Therefore, the difference between the work function of the first material and the work function of the second material and the difference between the work function of the third material and the work function of the second material can be made larger than in the MOSFET 100 according to the first embodiment.

Therefore, according to the MOSFET according to the first modification example of the first embodiment, it is possible to reduce the on-resistance more than in the MOSFET 100 according to the first embodiment, for example.

### Second Modification Example

A semiconductor device according to a second modification example of the first embodiment is different from the semiconductor device according to the first embodiment in that the first material, the second material, or the third material is a metal or a metal semiconductor compound.

In a MOSFET according to the second modification example of the first embodiment, at least one of the first material contained in the first portion 16a of the gate electrode 16, the second material contained in the second portion 16b of the gate electrode 16, and the third material contained in the third portion 16c of the gate electrode 16 is a metal or a metal semiconductor compound. All of the first material, the second material, and the third material may be metals or metal semiconductor compounds.

Since at least one of the first material, the second material, and the third material is a metal or a metal semiconductor compound, for example, the difference between the work function of the first material and the work function of the second material and the difference between the work function of the third material and the work function of the second material can be made larger than in the MOSFET 100 according to the first embodiment. In addition, for example, the electrical resistance of the gate electrode 16 can be reduced, allowing high-speed operation of the MOSFET.

According to the MOSFET according to the second modification example of the first embodiment, for example, it is possible to reduce the on-resistance more than in the MOSFET 100 according to the first embodiment. In addition, for example, high-speed operation of the MOSFET is possible.

### Third Modification Example

A semiconductor device according to a third modification example of the first embodiment is different from the semiconductor device according to the first embodiment in that a field plate electrode is provided.

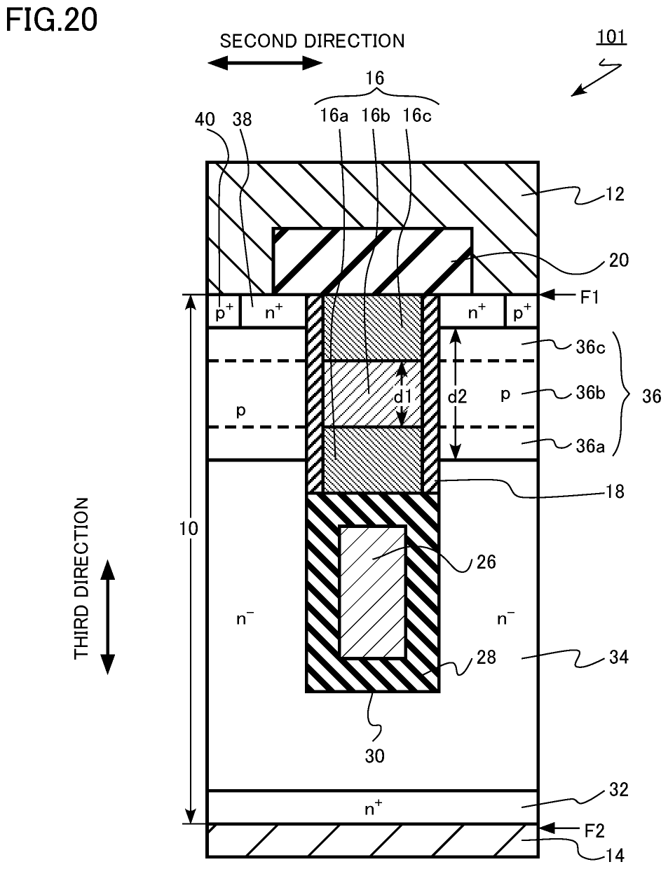

FIG. 20 is a schematic cross-sectional view of the semiconductor device according to the third modification example of the first embodiment. FIG. 20 is a diagram corresponding to FIG. 3 in the first embodiment.

A MOSFET 101 according to the third modification example of the first embodiment includes a silicon layer 10, a source electrode 12, a drain electrode 14, a gate electrode 16, a gate insulating layer 18, an interlayer insulating layer 20, a gate electrode pad 22, a gate wiring 24, a field plate electrode 26, and a field plate insulating layer 28.

The field plate electrode 26 is provided in the trench 30. The field plate electrode 26 is provided between the gate electrode 16 and the second face F2 in the third direction. The field plate electrode 26 extends in the first direction.

The field plate electrode 26 has a function of changing the electric field distribution in the drift region 34 when the MOSFET 101 is turned off, thereby increasing the breakdown voltage of the MOSFET 101.

The field plate electrode 26 is a conductor. The field plate electrode 26 is, for example, polycrystalline silicon containing n-type impurities or p-type impurities.

The field plate insulating layer 28 is provided between the field plate electrode 26 and the silicon layer 10. The field plate insulating layer 28 is provided between the field plate electrode 26 and the drift region 34. The field plate insulating layer 28 is provided between the field plate electrode 26 and the gate electrode 16. The field plate insulating layer 28 is, for example, a silicon oxide.

The thickness of the field plate insulating layer 28 is larger than the thickness of the gate insulating layer 18, for example.

Since the MOSFET 101 according to the third modification example of the first embodiment includes the field plate electrode 26, the MOSFET 101 has an increased breakdown voltage, for example. In addition, since the MOSFET 101 according to the third modification example of the first embodiment includes the field plate electrode 26, the impurity concentration in the drift region 34 can be reduced, for example. Therefore, for example, by reducing the resistance of the drift region 34, the on-resistance can be reduced.

According to the MOSFET 101 according to the third modification example of the first embodiment, for example, the breakdown voltage can be increased more than in the MOSFET 100 according to the first embodiment. In addition, for example, the on-resistance can be reduced more than in the MOSFET 100 according to the first embodiment.

As described above, according to the first embodiment and its modification examples, it is possible to realize a semiconductor device that can reduce on-resistance.

### Second Embodiment

A semiconductor device according to a second embodiment is different from the semiconductor device according to the first embodiment in that the first conductive type is p-type, the second conductive type is n-type, and the work function of the first material and the work function of the third material are larger than the work function of the second material. Hereinafter, the description of a part of the content overlapping the first embodiment may be omitted.

Hereinafter, a case where the first conductive type is p-type and the second conductive type is n-type will be described. That is, a case of a p-channel MOSFET using holes as carriers will be described.

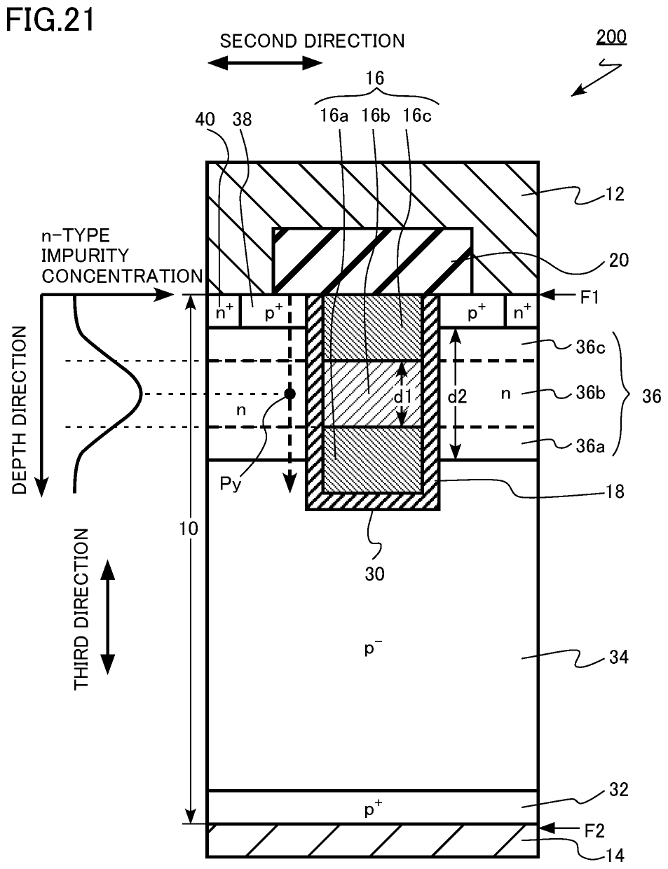

FIG. 21 is a schematic cross-sectional view of the semiconductor device according to the second embodiment. FIG. 21 is a diagram corresponding to FIG. 3 in the first embodiment. FIG. 21 shows the impurity concentration distribution in a part of the semiconductor layer.

A MOSFET 200 includes a silicon layer 10, a source electrode 12, a drain electrode 14, a gate electrode 16, a gate insulating layer 18, an interlayer insulating layer 20, a gate electrode pad 22, and a gate wiring 24.

The silicon layer 10 is an example of the semiconductor layer. The source electrode 12 is an example of the first electrode. The drain electrode 14 is an example of the second electrode.

The gate electrode 16 has a first portion 16a, a second portion 16b, and a third portion 16c. The gate wiring 24 includes a contact portion 24a.

The silicon layer 10 includes a trench 30, a p⁺-type drain region 32, a p⁻-type drift region 34, an n-type body region 36, a p⁺-type source region 38, and an n⁺-type contact region 40.

The drift region 34 is an example of the first semiconductor region. The body region 36 is an example of the second semiconductor region. The source region 38 is an example of the third semiconductor region.

The body region 36 includes a first region 36a, a second region 36b, and a third region 36c.

The p⁺-type drain region 32 contains p-type impurities. The p-type impurity is, for example, boron (B). The p-type impurity concentration in the drain region 32 is, for example, equal to or more than 1×10¹⁸ cm⁻³ and equal to or less than 1× 10²¹ cm⁻³.

The p⁻-type drift region 34 contains p-type impurities. The p-type impurity is, for example, boron (B). The p-type impurity concentration in the drift region 34 is, for example, equal to or more than 1×10¹⁵ cm⁻³ and equal to or less than 1×10¹⁸ cm⁻³.

The n-type body region 36 includes the first region 36a, the second region 36b, and the third region 36c.

The body region 36 contains n-type impurities. The n-type impurity is, for example, phosphorus (P) or arsenic (As). The n-type impurity concentration in the body region 36 is, for example, equal to or more than 1×10¹⁶ cm⁻³ and equal to or less than 1×10¹⁸ cm⁻³.

The n-type impurity concentration in the second region 36b is higher than the n-type impurity concentration in the first region 36a. The n-type impurity concentration in the second region 36b is higher than the n-type impurity concentration in the third region 36c.

As shown in FIG. 21, the n-type impurity concentration in the depth direction in a region of the body region 36 along the gate insulating layer 18 is maximum at a position Py. The position Py is in the second region 36b. The n-type impurity concentration distribution in the depth direction in the region of the body region 36 along the gate insulating layer 18 has a maximum peak in the second region 36b.

The p⁺-type source region 38 contains p-type impurities. The p-type impurity is, for example, boron (B). The p-type impurity concentration in the source region 38 is, for example, equal to or more than 1×10¹⁹ cm⁻³ and equal to or less than 1×10²¹ cm⁻³.

The n⁺-type contact region 40 contains n-type impurities. The n-type impurity is, for example, phosphorus (P) or arsenic (As). The n-type impurity concentration in the contact region 40 is, for example, equal to or more than 1×10¹⁹ cm⁻³ and equal to or less than 1×10²¹ cm⁻³. The n-type impurity concentration in the contact region 40 is higher than the n-type impurity concentration in the body region 36.

The gate electrode 16 has a first portion 16a, a second portion 16b, and a third portion 16c. The first portion 16a contains a first material. The second portion 16b contains a second material. The third portion 16c contains a third material.

The work function of the first material is larger than the work function of the second material. The work function of the third material is larger than the work function of the second material.

The difference between the work function of the first material and the work function of the second material is, for example, equal to or more than 0.2 eV and equal to or less than 4.0 eV. In addition, the difference between the work function of the third material and the work function of the second material is, for example, equal to or more than 0.2 eV and equal to or less than 4.0 eV.

The first material, the second material, and the third material are p-type polycrystalline silicon containing p-type impurities. The p-type impurity concentration of the first material is higher than the p-type impurity concentration of the second material. The p-type impurity concentration of the third material is higher than the p-type impurity concentration of the second material.

In p-type polycrystalline silicon, the higher the p-type impurity concentration, the smaller the energy difference between the Fermi level and the top of the valence band, and the larger the work function.

The length (d1 in FIG. 21) of the second portion 16b in the third direction is, for example, equal to or more than 20% and equal to or less than 70% of the length (d2 in FIG. 21) between the drift region 34 and the source region 38 in the third direction.

As shown in FIG. 21, the position Py where the n-type impurity concentration in the depth direction in a region of the body region 36 along the gate insulating layer 18 is maximum faces the second portion 16b in the second direction, for example.

In the MOSFET 200 according to the second embodiment, the gate electrode 16 includes a first portion 16a, a second portion 16b, and a third portion 16c. The work function of the first material contained in the first portion 16a is larger than the work function of the second material contained in the second portion 16b. In addition, the work function of the third material contained in the third portion 16c is larger than the work function of the second material contained in the second portion 16b.

Since the work function of the first material is larger than the work function of the second material, the threshold voltage of the MOSFET formed by the first portion 16a, the gate insulating layer 18, and the first region 36a is lower than the threshold voltage of the MOSFET formed by the second portion 16b, the gate insulating layer 18, and the second region 36b. In other words, the threshold voltage of the MOSFET having the first portion 16a as its gate electrode is lower than the threshold voltage of the MOSFET having the second portion 16b as its gate electrode.

Similarly, since the work function of the third material is larger than the work function of the second material, the threshold voltage of the MOSFET formed by the third portion 16c, the gate insulating layer 18, and the third region 36c is lower than the threshold voltage of the MOSFET formed by the second portion 16b, the gate insulating layer 18, and the second region 36b. In other words, the threshold voltage of the MOSFET having the third portion 16c as its gate electrode is lower than the threshold voltage of the MOSFET having the second portion 16b as its gate electrode.

In the MOSFET 200 according to the second embodiment, since the threshold voltage of the MOSFET having the first portion 16a as its gate electrode and the threshold voltage of the MOSFET having the third portion 16c as its gate electrode are low, the channel resistance of the channel formed in the first region 36a and the channel resistance of the channel formed in the third region 36c are reduced. Therefore, the on-resistance of the MOSFET 200 is reduced.

On the other hand, since the threshold voltage of the MOSFET having the second portion 16b as its gate electrode is kept relatively high, the threshold voltage of the MOSFET 200 can be kept high.

For example, as shown in FIG. 21, a case is considered in which the n-type impurity concentration distribution in the depth direction in a region of the body region 36 along the gate insulating layer 18 has a maximum peak in the second region 36b. In this case, it is preferable that the position Py where the n-type impurity concentration is maximum faces the second portion 16b in the second direction. Since the position Py where the n-type impurity concentration is maximum faces the second portion 16b, the threshold voltage of the MOSFET having the second portion 16b as its gate electrode can be further increased.

From the viewpoint of reducing the on-resistance of the MOSFET 200, the difference between the work function of the first material and the work function of the second material is preferably equal to or more than 0.2 eV, more preferably equal to or more than 0.5 eV, and even more preferably equal to or more than 1.0 eV, for example.

Similarly, from the viewpoint of reducing the on-resistance of the MOSFET 200, the difference between the work function of the third material and the work function of the second material is preferably equal to or more than 0.2 eV, more preferably equal to or more than 0.5 eV, and even more preferably equal to or more than 1.0 eV, for example.

The length (d1 in FIG. 21) of the second portion 16b in the third direction is preferably equal to or more than 20% and equal to or less than 70% of the length (d2 in FIG. 21) between the drift region 34 and the source region 38 in the third direction, more preferably equal to or more than 30% and equal to or less than 60%, and even more preferably equal to or more than 40% and equal to or less than 50%, for example. By making the length (d1 in FIG. 21) of the second portion 16b in the third direction exceed the lower limit value described above, a decrease in threshold voltage can be suppressed. In addition, by making the length (d1 in FIG. 21) of the second portion 16b in the third direction less than the upper limit value described above, the on-resistance is further reduced.

As described above, according to the MOSFET 200 according to the second embodiment, it is possible to reduce the on-resistance.

### First Modification Example

A semiconductor device according to a first modification example of the second embodiment is different from the semiconductor device according to the second embodiment in that the second material is n-type polycrystalline silicon.

In the MOSFET according to the second modification example of the second embodiment, the second material contained in the second portion 16b of the gate electrode 16 is n-type polycrystalline silicon. Then, the first material contained in the first portion 16a of the gate electrode 16 and the third material contained in the third portion 16c of the gate electrode 16 are p-type polycrystalline silicon.

Since the n-type polycrystalline silicon is used as the second material, the work function of the second material is smaller than that when the second material is p-type polycrystalline silicon. Therefore, the difference between the work function of the first material and the work function of the second material and the difference between the work function of the third material and the work function of the second material can be made larger than in the MOSFET 200 according to the second embodiment.

According to the MOSFET according to the first modification example of the second embodiment, for example, it is possible to reduce the on-resistance more than in the MOSFET 200 according to the second embodiment.

### Second Modification Example

A semiconductor device according to a second modification example of the second embodiment is different from the semiconductor device according to the second embodiment in that the first material, the second material, or the third material is a metal or a metal semiconductor compound.

In a MOSFET according to the second modification example of the second embodiment, at least one of the first material contained in the first portion 16a of the gate electrode 16, the second material contained in the second portion 16b of the gate electrode 16, and the third material contained in the third portion 16c of the gate electrode 16 is a metal or a metal semiconductor compound. All of the first material, the second material, and the third material may be metals or metal semiconductor compounds.

Since at least one of the first material, the second material, and the third material is a metal or a metal semiconductor compound, for example, the difference between the work function of the first material and the work function of the second material and the difference between the work function of the third material and the work function of the second material can be made larger than in the MOSFET 200 according to the second embodiment. In addition, for example, the electrical resistance of the gate electrode 16 can be reduced, allowing high-speed operation of the MOSFET.

According to the MOSFET according to the second modification example of the second embodiment, for example, it is possible to reduce the on-resistance more than in the MOSFET 200 according to the second embodiment. In addition, for example, high-speed operation of the MOSFET is possible.

### Third Modification Example

A semiconductor device according to a third modification example of the second embodiment is different from the semiconductor device according to the second embodiment in that a field plate electrode is provided.

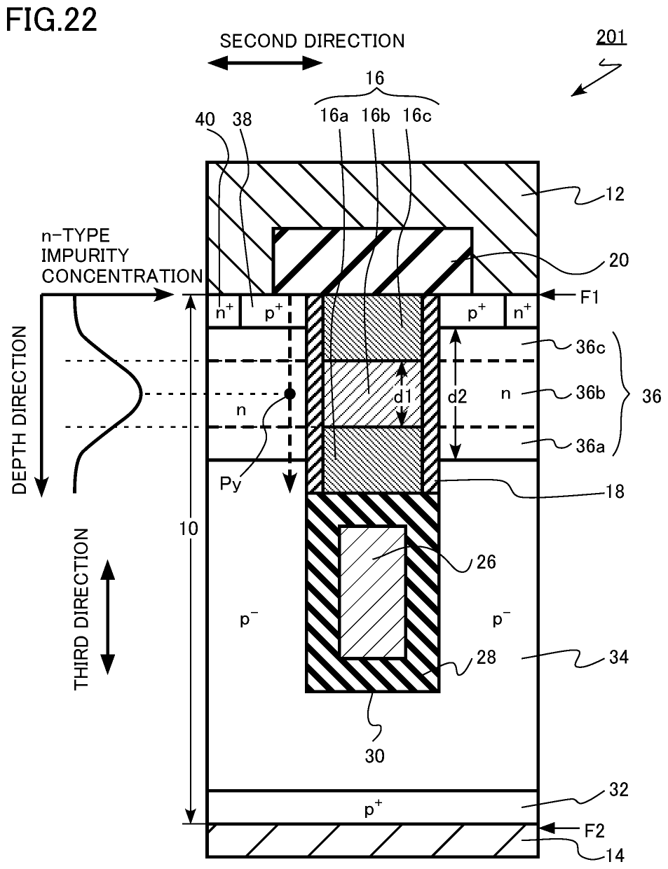

FIG. 22 is a schematic cross-sectional view of the semiconductor device according to the third modification example of the second embodiment. FIG. 22 is a diagram corresponding to FIG. 21 in the second embodiment.

A MOSFET 201 according to the third modification example of the second embodiment includes a silicon layer 10, a source electrode 12, a drain electrode 14, a gate electrode 16, a gate insulating layer 18, an interlayer insulating layer 20, a gate electrode pad 22, a gate wiring 24, a field plate electrode 26, and a field plate insulating layer 28.

The field plate electrode 26 is provided in the trench 30. The field plate electrode 26 is provided between the gate electrode 16 and the second face F2 in the third direction. The field plate electrode 26 extends in the first direction.

The field plate electrode 26 has a function of changing the electric field distribution in the drift region 34 when the MOSFET 201 is turned off, thereby increasing the breakdown voltage of the MOSFET 201.

The field plate electrode 26 is a conductor. The field plate electrode 26 is, for example, polycrystalline silicon containing n-type impurities or p-type impurities.

The field plate insulating layer 28 is provided between the field plate electrode 26 and the silicon layer 10. The field plate insulating layer 28 is provided between the field plate electrode 26 and the drift region 34. The field plate insulating layer 28 is provided between the field plate electrode 26 and the gate electrode 16. The field plate insulating layer 28 is, for example, a silicon oxide.

The thickness of the field plate insulating layer 28 is larger than the thickness of the gate insulating layer 18, for example.

Since the MOSFET 201 according to the third modification example of the second embodiment includes the field plate electrode 26, the MOSFET 101 has an increased breakdown voltage, for example. In addition, since the MOSFET 201 according to the third modification example of the second embodiment includes the field plate electrode 26, the impurity concentration in the drift region 34 can be reduced, for example. Therefore, for example, by reducing the resistance of the drift region 34, the on-resistance can be reduced.

According to the MOSFET 201 according to the third modification example of the second embodiment, for example, the breakdown voltage can be increased more than in the MOSFET 200 according to the second embodiment. In addition, for example, the on-resistance can be reduced more than in the MOSFET 200 according to the second embodiment.

As described above, according to the second embodiment and its modification examples, it is possible to realize a semiconductor device that can reduce on-resistance.

### Third Embodiment

A semiconductor device according to a third embodiment is different from the semiconductor device according to the first embodiment in that a first insulating film is provided between a first portion and a second portion and a second insulating film is provided between the second portion and a third portion. Hereinafter, the description of a part of the content overlapping the first embodiment may be omitted.

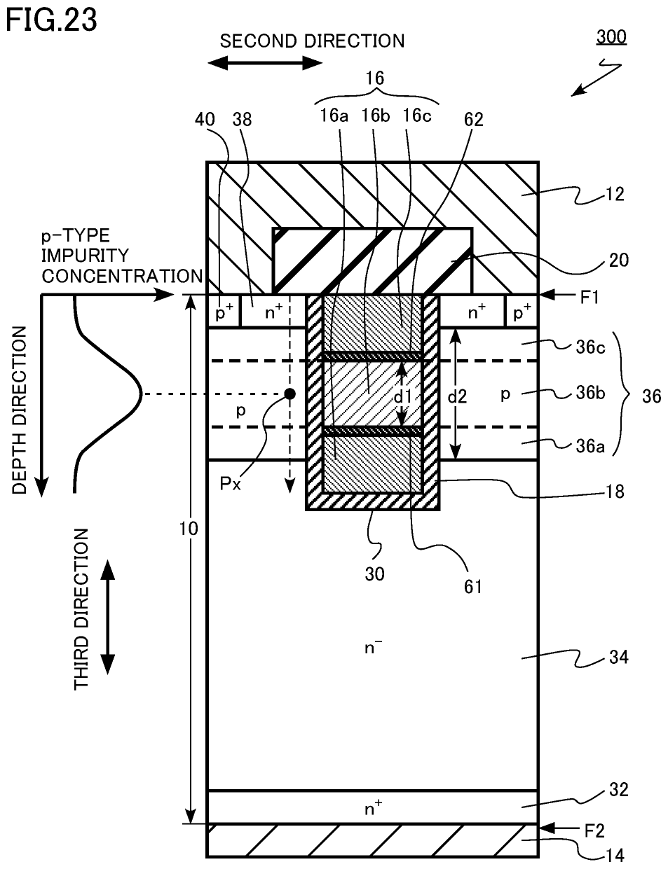

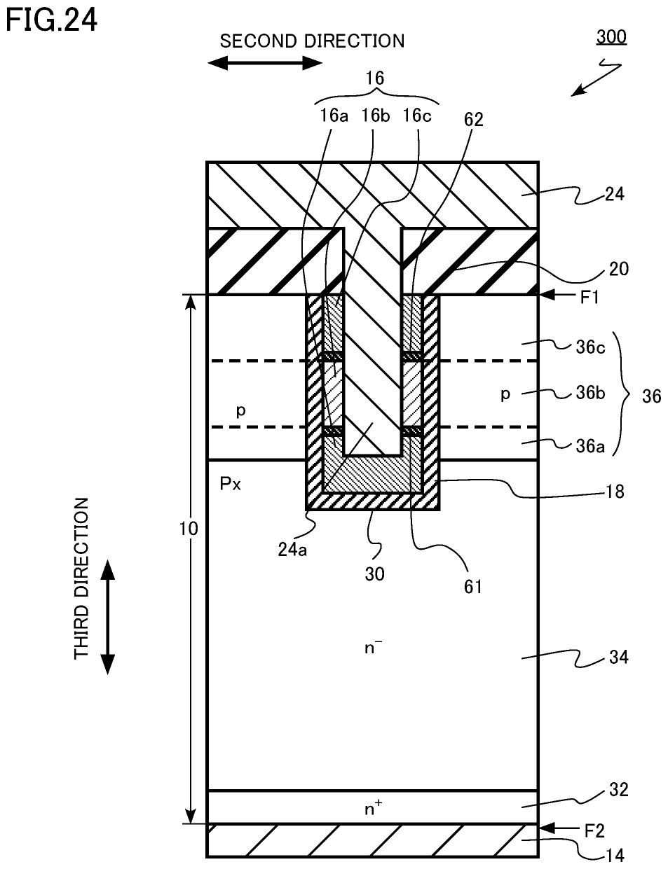

FIGS. 23 and 24 are schematic cross-sectional views of the semiconductor device according to the third embodiment. FIG. 23 is a diagram corresponding to FIGS. 3 and 4 in the first embodiment. FIG. 23 shows the impurity concentration distribution in a part of the semiconductor layer.

A MOSFET 300 according to the third embodiment includes a silicon layer 10, a source electrode 12, a drain electrode 14, a gate electrode 16, a gate insulating layer 18, an interlayer insulating layer 20, a gate electrode pad 22, a gate wiring 24, a first insulating film 61, a second insulating film 62.

The first material, the second material, and the third material are, for example, polycrystalline silicon containing n-type impurities or p-type impurities.

The first insulating film 61 is provided between the first portion 16a and the second portion 16b. The first insulating film 61 contains, for example, oxide, nitride, or oxynitride. The first insulating film 61 contains, for example, silicon oxide, silicon nitride, or silicon oxynitride.

The thickness of the first insulating film 61 is smaller than the thickness of the gate insulating layer 18, for example.

The first insulating film 61 has a function of, for example, suppressing the diffusion of impurities between the first portion 16a and the second portion 16b. In the first insulating film 61, for example, impurities are diffused between the first portion 16a and the second portion 16b, and changes in the work function of the first material and the work function of the second material from desired values are suppressed.

The second insulating film 62 is provided between the third portion 16c and the second portion 16b. The second insulating film 62 contains, for example, oxide, nitride, or oxynitride. The second insulating film 62 contains, for example, silicon oxide, silicon nitride, or silicon oxynitride.

The thickness of the second insulating film 62 is, for example, smaller than the thickness of the gate insulating layer 18.

The second insulating film 62 has a function of, for example, suppressing the diffusion of impurities between the third portion 16c and the second portion 16b. In the second insulating film 62, for example, impurities are diffused between the third portion 16c and the second portion 16b, and changes in the work function of the third material and the work function of the second material from desired values are suppressed.

As shown in FIG. 24, the gate wiring 24 is connected to the gate electrode 16 in the region Y. The contact portion 24a of the gate wiring 24 is connected to the gate electrode 16 in the region Y.

The contact portion 24a passes through the interlayer insulating layer 20, the third portion 16c, the second insulating film 62, the second portion 16b, and the first insulating film 61 to reach the first portion 16a.

The contact portion 24a is in contact with, for example, the third portion 16c, the second portion 16b, and the first portion 16a of the gate electrode 16. The contact portion 24a is electrically and physically connected to, for example, the third portion 16c, the second portion 16b, and the first portion 16a of the gate electrode 16. The first portion 16a, the second portion 16b, and the third portion 16c are electrically connected to each other by the contact portion 24a.

As described above, according to the third embodiment, as in the first embodiment, it is possible to realize a semiconductor device that can reduce on-resistance.

### Fourth Embodiment

A semiconductor device according to a fourth embodiment is different from the semiconductor device according to the second embodiment in that a first insulating film is provided between a first portion and a second portion and a second insulating film is provided between the second portion and a third portion. In addition, the semiconductor device according to the fourth embodiment is different from the semiconductor device according to the third embodiment in that the first conductive type is p-type, the second conductive type is n-type, and the work function of the first material and the work function of the third material are larger than the work function of the second material. Hereinafter, the description of a part of the content overlapping the second or third embodiment may be omitted.

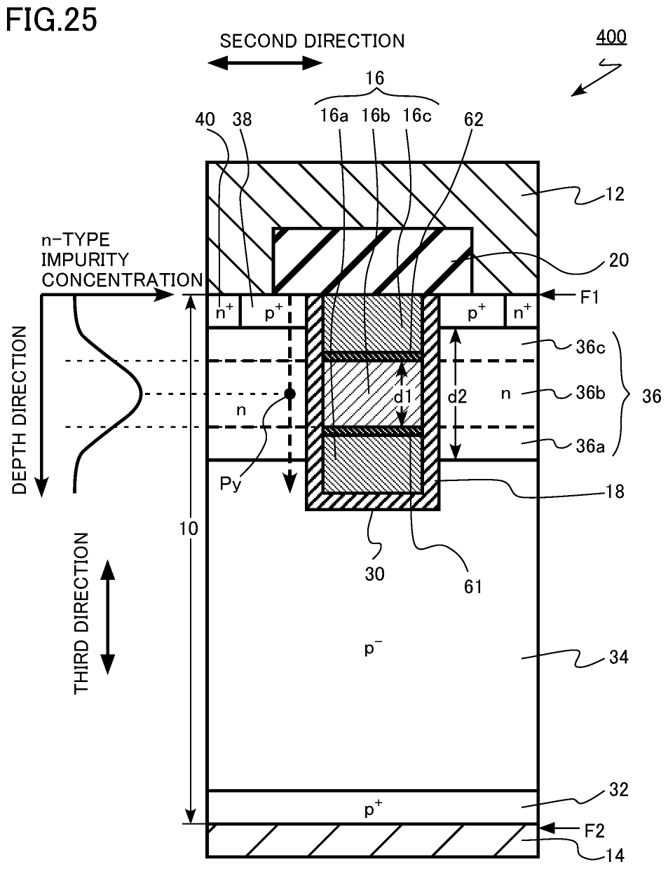

FIG. 25 is a schematic cross-sectional view of the semiconductor device according to the fourth embodiment. FIG. 25 is a diagram corresponding to FIG. 21 in the second embodiment. FIG. 25 shows the impurity concentration distribution in a part of the semiconductor layer.

A MOSFET 400 according to the fourth embodiment includes a silicon layer 10, a source electrode 12, a drain electrode 14, a gate electrode 16, a gate insulating layer 18, an interlayer insulating layer 20, a gate electrode pad 22, a gate wiring 24, a first insulating film 61, and a second insulating film 62.

The first material, the second material, and the third material are, for example, polycrystalline silicon containing n-type impurities or p-type impurities.

The first insulating film 61 is provided between the first portion 16a and the second portion 16b. The first insulating film 61 contains, for example, oxide, nitride, or oxynitride. The first insulating film 61 contains, for example, silicon oxide, silicon nitride, or silicon oxynitride.

The thickness of the first insulating film 61 is smaller than the thickness of the gate insulating layer 18, for example.

The first insulating film 61 has a function of, for example, suppressing the diffusion of impurities between the first portion 16a and the second portion 16b. In the first insulating film 61, for example, impurities are diffused between the first portion 16a and the second portion 16b, and changes in the work function of the first material and the work function of the second material from desired values are suppressed.

The second insulating film 62 is provided between the third portion 16c and the second portion 16b. The second insulating film 62 contains, for example, oxide, nitride, or oxynitride. The second insulating film 62 contains, for example, silicon oxide, silicon nitride, or silicon oxynitride.

The thickness of the second insulating film 62 is smaller than the thickness of the gate insulating layer 18, for example.

The second insulating film 62 has a function of, for example, suppressing the diffusion of impurities between the third portion 16c and the second portion 16b. In the second insulating film 62, for example, impurities are diffused between the third portion 16c and the second portion 16b, and changes in the work function of the third material and the work function of the second material from desired values are suppressed.

The first portion 16a, the second portion 16b, and the third portion 16c are electrically connected to each other by a contact portion (not shown).

As described above, according to the fourth embodiment, as in the second embodiment, it is possible to realize a semiconductor device that can reduce on-resistance.

### Fifth Embodiment

A semiconductor device according to a fifth embodiment includes: a semiconductor layer having a first face and a second face opposite to the first face, the semiconductor layer including a first semiconductor region of n-type, a second semiconductor region of p-type provided between the first semiconductor region and the first face, and a third semiconductor region of n-type provided between the second semiconductor region and the first face; a first electrode provided on the first face side of the semiconductor layer and electrically connected to the third semiconductor region; a second electrode provided on the second face side of the semiconductor layer; a gate electrode provided in the semiconductor layer and facing the first semiconductor region, the second semiconductor region, and the third semiconductor region; and a gate insulating layer provided between the gate electrode and the first semiconductor region, between the gate electrode and the second semiconductor region, and between the gate electrode and the third semiconductor region. The second semiconductor region includes a first region and a second region. The first region is provided between the second region and the first semiconductor region or between the second region and the third semiconductor region. The gate electrode includes a first portion and a second portion. The first portion faces the first region, and the second portion faces the second region. The first portion contains a first material, and the second portion contains a second material. The first material is n-type polycrystalline silicon. A work function of the first material is smaller than a work function of the second material.

The semiconductor device according to the fifth embodiment is different from the semiconductor device according to the first embodiment in that the gate electrode does not include a third portion. Hereinafter, the description of a part of the content overlapping the first embodiment may be omitted.

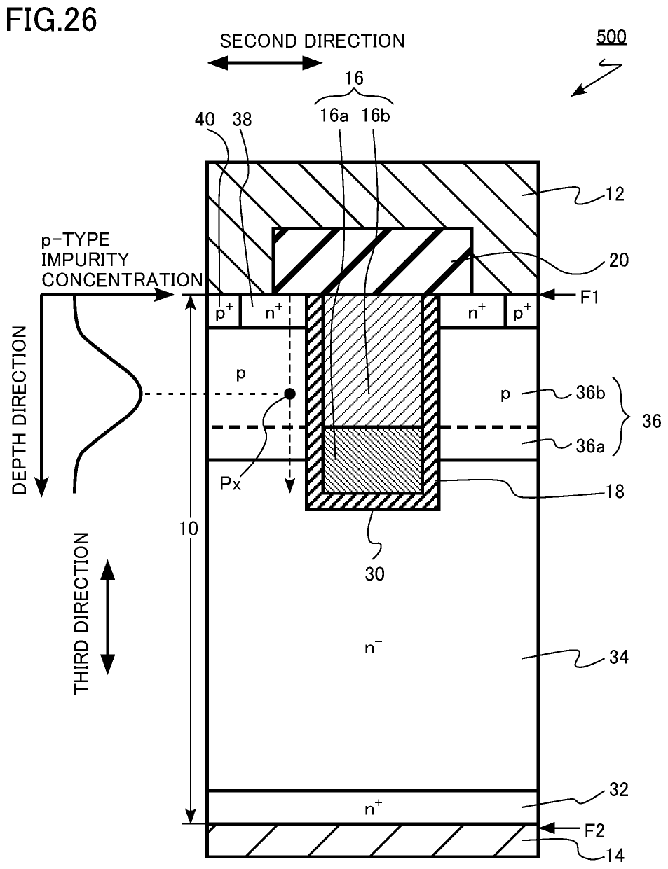

FIG. 26 is a schematic cross-sectional view of the semiconductor device according to the fifth embodiment. FIG. 26 is a diagram corresponding to FIG. 3 in the first embodiment. FIG. 26 shows the impurity concentration distribution in a part of the semiconductor layer.

A MOSFET 500 according to the fifth embodiment includes a silicon layer 10, a source electrode 12, a drain electrode 14, a gate electrode 16, a gate insulating layer 18, an interlayer insulating layer 20, a gate electrode pad 22, and a gate wiring 24.

The gate electrode 16 has a first portion 16a and a second portion 16b.

The silicon layer 10 includes a trench 30, an n⁺-type drain region 32, an n⁻-type drift region 34, a p-type body region 36, an n⁺-type source region 38, and a p⁺-type contact region 40.

The p-type body region 36 is provided in the silicon layer 10. The body region 36 is provided between the drift region 34 and the first face F1. When the MOSFET 500 is turned on, a channel is formed in a region of the body region 36 along the gate insulating layer 18.

The body region 36 includes a first region 36a and a second region 36b. The first region 36a is provided between the second region 36b and the drift region 34.

The body region 36 contains p-type impurities. The p-type impurity is, for example, boron (B). The p-type impurity concentration in the body region 36 is, for example, equal to or more than 1×10¹⁶ cm⁻³ and equal to or less than 1×10¹⁸ cm⁻³.

The p-type impurity concentration in the second region 36b is higher than the p-type impurity concentration in the first region 36a.

As shown in FIG. 26, the p-type impurity concentration in the depth direction in a region of the body region 36 along the gate insulating layer 18 is maximum at a position Px. The position Px is in the second region 36b. The p-type impurity concentration distribution in the depth direction in the region along the gate insulating layer 18 of the body region 36 has a maximum peak in the second region 36b.

The gate electrode 16 has a first portion 16a and a second portion 16b. The first portion 16a is provided on the second face F2 side with respect to the second portion 16b.

The second portion 16b is in contact with the first portion 16a. The first portion 16a and the second portion 16b are electrically connected to each other.

The first portion 16a faces the first region 36a of the body region 36 in the second direction. The second portion 16b faces the second region 36b of the body region 36 in the second direction.

The first portion 16a contains a first material. The second portion 16b contains a second material. The first portion 16a is formed of, for example, a first material. The second portion 16b is formed of, for example, a second material.

The work function of the first material is smaller than the work function of the second material. The difference between the work function of the first material and the work function of the second material is, for example, equal to or more than 0.2 eV and equal to or less than 4.0 eV.

The first material and the second material are n-type polycrystalline silicon containing n-type impurities. The n-type impurity concentration of the first material is higher than the n-type impurity concentration of the second material.

As shown in FIG. 26, the position Px where the p-type impurity concentration in the depth direction in a region of the body region 36 along the gate insulating layer 18 is maximum faces the second portion 16b in the second direction, for example.

In the MOSFET 500 according to the fifth embodiment, the gate electrode 16 includes a first portion 16a and a second portion 16b. The work function of the first material contained in the first portion 16a is smaller than the work function of the second material contained in the second portion 16b.

Since the work function of the first material is smaller than the work function of the second material, the threshold voltage of the MOSFET formed by the first portion 16a, the gate insulating layer 18, and the first region 36a is lower than the threshold voltage of the MOSFET formed by the second portion 16b, the gate insulating layer 18, and the second region 36b. In other words, the threshold voltage of the MOSFET having the first portion 16a as its gate electrode is lower than the threshold voltage of the MOSFET having the second portion 16b as its gate electrode.

In the MOSFET 500 according to the fifth embodiment, since the threshold voltage of the MOSFET having the first portion 16a as its gate electrode is low, the channel resistance of the channel formed in the first region 36a is reduced. Therefore, the on-resistance of the MOSFET 500 is reduced.

On the other hand, since the threshold voltage of the MOSFET having the second portion 16b as its gate electrode is kept relatively high, the threshold voltage of the MOSFET 500 can be kept high.

For example, as shown in FIG. 26, since the position Px where the p-type impurity concentration is maximum faces the second portion 16b, the threshold voltage of the MOSFET having the second portion 16b as its gate electrode can be further increased.

From the viewpoint of reducing the on-resistance of the MOSFET 500, the difference between the work function of the first material and the work function of the second material is preferably equal to or more than 0.2 eV, more preferably equal to or more than 0.5 eV, and even more preferably equal to or more than 1.0 eV, for example.

As described above, according to the MOSFET 500 according to the fifth embodiment, it is possible to reduce the on-resistance.

### First Modification Example

A semiconductor device according to a first modification example of the fifth embodiment is different from the semiconductor device according to the fifth embodiment in that the second material is p-type polycrystalline silicon.

In a MOSFET according to the first modification example of the fifth embodiment, the second material contained in the second portion 16b of the gate electrode 16 is p-type polycrystalline silicon. Then, the first material contained in the first portion 16a of the gate electrode 16 is n-type polycrystalline silicon.

Since the p-type polycrystalline silicon is used as the second material, the work function of the second material is larger than that when the second material is n-type polycrystalline silicon. Therefore, the difference between the work function of the first material and the work function of the second material can be made larger than in the MOSFET 500 according to the fifth embodiment.

According to the MOSFET according to the first modification example of the fifth embodiment, for example, it is possible to reduce the on-resistance more than in the MOSFET 500 according to the fifth embodiment.

### Second Modification Example

A semiconductor device according to a second modification example of the fifth embodiment is different from the semiconductor device according to the fifth embodiment in that the first region of the second semiconductor region is provided between the second region and the third semiconductor region.

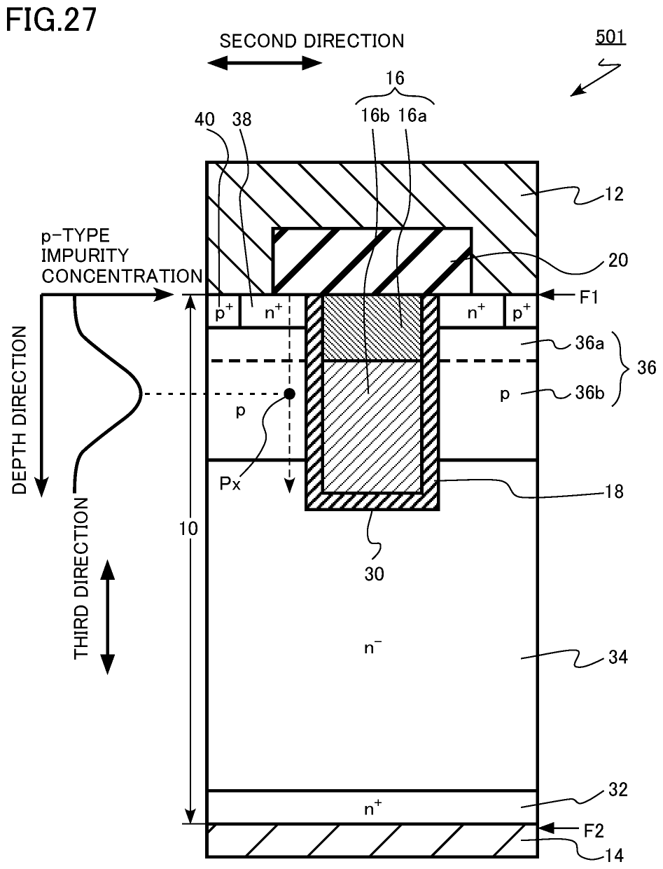

FIG. 27 is a schematic cross-sectional view of the semiconductor device according to the second modification example of the fifth embodiment. FIG. 27 is a diagram corresponding to FIG. 26 in the fifth embodiment. FIG. 27 shows the impurity concentration distribution in a part of the semiconductor layer. The semiconductor device according to the second modification example of the fifth embodiment is a MOSFET 501.

A p-type body region 36 includes a first region 36a and a second region 36b. The first region 36a is provided between the second region 36b and a source region 38.

The body region 36 contains p-type impurities. The p-type impurity is, for example, boron (B). The p-type impurity concentration in the body region 36 is, for example, equal to or more than 1×10¹⁶ cm⁻³ and equal to or less than 1×10¹⁸ cm⁻³.

The p-type impurity concentration in the second region 36b is higher than the p-type impurity concentration in the first region 36a.

As shown in FIG. 27, the p-type impurity concentration in the depth direction in a region of the body region 36 along the gate insulating layer 18 is maximum at a position Px. The position Px is in the second region 36b. The p-type impurity concentration distribution in the depth direction in the region along the gate insulating layer 18 of the body region 36 has a maximum peak in the second region 36b.

A gate electrode 16 has a first portion 16a and a second portion 16b. The first portion 16a is provided on the first face F1 side with respect to the second portion 16b.

The second portion 16b is in contact with the first portion 16a. The first portion 16a and the second portion 16b are electrically connected to each other.

The first portion 16a faces the first region 36a of the body region 36 in the second direction. The second portion 16b faces the second region 36b of the body region 36 in the second direction.

The first portion 16a contains a first material. The second portion 16b contains a second material. The first portion 16a is formed of, for example, a first material. The second portion 16b is formed of, for example, a second material.

The work function of the first material is smaller than the work function of the second material. The difference between the work function of the first material and the work function of the second material is, for example, equal to or more than 0.2 eV and equal to or less than 4.0 eV.

The first material and the second material are n-type polycrystalline silicon containing n-type impurities. The n-type impurity concentration of the first material is higher than the n-type impurity concentration of the second material.

As shown in FIG. 27, the position Px where the p-type impurity concentration in the depth direction in a region of the body region 36 along the gate insulating layer 18 is maximum faces the second portion 16b in the second direction, for example.

In the MOSFET 501 according to the second modification example of the fifth embodiment, the gate electrode 16 includes the first portion 16a and the second portion 16b. The work function of the first material contained in the first portion 16a is smaller than the work function of the second material contained in the second portion 16b.

Since the work function of the first material is smaller than the work function of the second material, the threshold voltage of the MOSFET formed by the first portion 16a, the gate insulating layer 18, and the first region 36a is lower than the threshold voltage of the MOSFET formed by the second portion 16b, the gate insulating layer 18, and the second region 36b. In other words, the threshold voltage of the MOSFET having the first portion 16a as its gate electrode is lower than the threshold voltage of the MOSFET having the second portion 16b as its gate electrode.

In the MOSFET 501 according to the second modification example of the fifth embodiment, since the threshold voltage of the MOSFET having the first portion 16a as its gate electrode is low, the channel resistance of the channel formed in the first region 36a is reduced. Therefore, the on-resistance of the MOSFET 501 is reduced.

On the other hand, since the threshold voltage of the MOSFET having the second portion 16b as its gate electrode is kept relatively high, the threshold voltage of the MOSFET 501 can be kept high.

For example, as shown in FIG. 27, since the position Px where the p-type impurity concentration is maximum faces the second portion 16b, the threshold voltage of the MOSFET having the second portion 16b as its gate electrode can be further increased.

From the viewpoint of reducing the on-resistance of the MOSFET 501, the difference between the work function of the first material and the work function of the second material is preferably equal to or more than 0.2 eV, more preferably equal to or more than 0.5 eV, and even more preferably equal to or more than 1.0 eV, for example.

According to the MOSFET 501 according to the second modification example of the fifth embodiment, it is possible to reduce the on-resistance as in the MOSFET 500 according to the fifth embodiment.

As described above, according to the fifth embodiment and its modification examples, it is possible to realize a semiconductor device that can reduce on-resistance.

### Sixth Embodiment

A semiconductor device according to a sixth embodiment includes: a semiconductor layer having a first face and a second face opposite to the first face, the semiconductor layer including a first semiconductor region of p-type, a second semiconductor region of n-type provided between the first semiconductor region and the first face, and a third semiconductor region of p-type provided between the second semiconductor region and the first face; a first electrode provided on the first face side of the semiconductor layer and electrically connected to the third semiconductor region; a second electrode provided on the second face side of the semiconductor layer; a gate electrode provided in the semiconductor layer and facing the first semiconductor region, the second semiconductor region, and the third semiconductor region; and a gate insulating layer provided between the gate electrode and the first semiconductor region, between the gate electrode and the second semiconductor region, and between the gate electrode and the third semiconductor region. The second semiconductor region includes a first region and a second region. The first region is provided between the second region and the first semiconductor region or between the second region and the third semiconductor region. The gate electrode includes a first portion and a second portion. The first portion faces the first region, and the second portion faces the second region. The first portion contains a first material, and the second portion contains a second material. The work function of the first material is larger than the work function of the second material.

The semiconductor device according to the sixth embodiment is different from the semiconductor device according to the second embodiment in that the gate electrode does not include a third portion. Hereinafter, the description of a part of the content overlapping the second embodiment may be omitted.

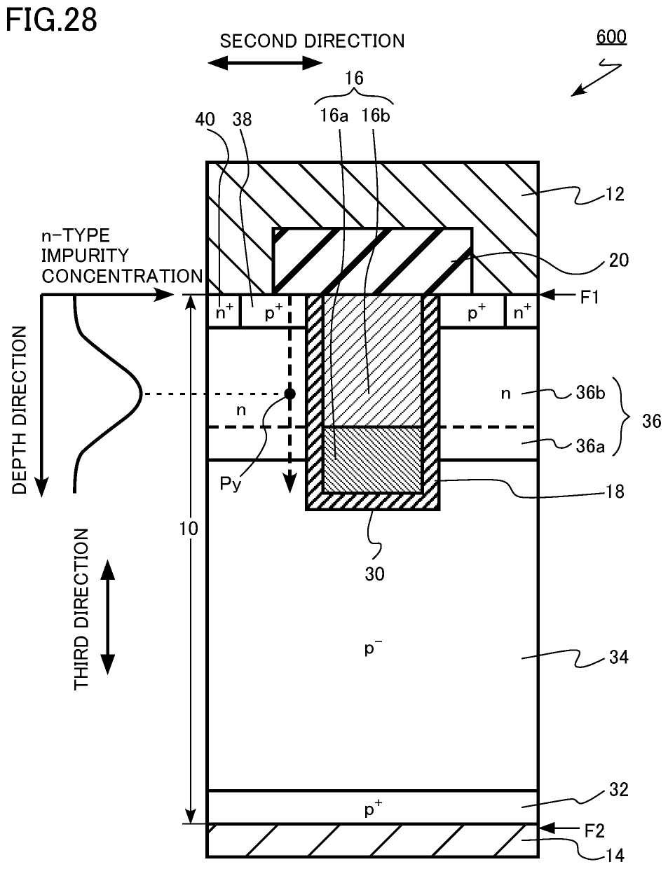

FIG. 28 is a schematic cross-sectional view of the semiconductor device according to the sixth embodiment. FIG. 28 is a diagram corresponding to FIG. 21 in the second embodiment. FIG. 28 shows the impurity concentration distribution in a part of the semiconductor layer.

A MOSFET 600 according to the sixth embodiment includes a silicon layer 10, a source electrode 12, a drain electrode 14, a gate electrode 16, a gate insulating layer 18, an interlayer insulating layer 20, a gate electrode pad 22, and a gate wiring 24.

The gate electrode 16 has a first portion 16a and a second portion 16b.

The silicon layer 10 includes a trench 30, a p⁺-type drain region 32, a p⁻-type drift region 34, an n-type body region 36, a p⁺-type source region 38, and an n⁺-type contact region 40.

The n-type body region 36 is provided in the silicon layer 10. The body region 36 is provided between the drift region 34 and the first face F1. When the MOSFET 600 is turned on, a channel is formed in a region of the body region 36 along the gate insulating layer 18.

The body region 36 includes a first region 36a and a second region 36b. The first region 36a is provided between the second region 36b and the drift region 34.

The body region 36 contains n-type impurities. The n-type impurity is, for example, phosphorus (P) or arsenic (As). The n-type impurity concentration in the body region 36 is, for example, equal to or more than 1×10¹⁶ cm⁻³ and equal to or less than 1×10¹⁸ cm⁻³.

The n-type impurity concentration in the second region 36b is higher than the n-type impurity concentration in the first region 36a.

As shown in FIG. 28, the n-type impurity concentration in the depth direction in a region of the body region 36 along the gate insulating layer 18 is maximum at the position Py. The position Py is in the second region 36b. The n-type impurity concentration distribution in the depth direction in the region of the body region 36 along the gate insulating layer 18 has a maximum peak in the second region 36b.

The gate electrode 16 has a first portion 16a and a second portion 16b. The first portion 16a is provided on the second face F2 side with respect to the second portion 16b.

The second portion 16b is in contact with the first portion 16a. The first portion 16a and the second portion 16b are electrically connected to each other.

The first portion 16a faces the first region 36a of the body region 36 in the second direction. The second portion 16b faces the second region 36b of the body region 36 in the second direction.

The first portion 16a contains a first material. The second portion 16b contains a second material. The first portion 16a is formed of, for example, a first material. The second portion 16b is formed of, for example, a second material.

The work function of the first material is larger than the work function of the second material. The difference between the work function of the first material and the work function of the second material is, for example, equal to or more than 0.2 eV and equal to or less than 4.0 eV.

The first material and the second material are p-type polycrystalline silicon containing p-type impurities. The p-type impurity concentration of the first material is higher than the p-type impurity concentration of the second material.

As shown in FIG. 28, the position Py where the n-type impurity concentration in the depth direction in a region of the body region 36 along the gate insulating layer 18 is maximum faces the second portion 16b in the second direction, for example.

In the MOSFET 600 according to the sixth embodiment, the gate electrode 16 includes a first portion 16a and a second portion 16b. The work function of the first material contained in the first portion 16a is larger than the work function of the second material contained in the second portion 16b.

Since the work function of the first material is larger than the work function of the second material, the threshold voltage of the MOSFET formed by the first portion 16a, the gate insulating layer 18, and the first region 36a is lower than the threshold voltage of the MOSFET formed by the second portion 16b, the gate insulating layer 18, and the second region 36b. In other words, the threshold voltage of the MOSFET having the first portion 16a as its gate electrode is lower than the threshold voltage of the MOSFET having the second portion 16b as its gate electrode.

In the MOSFET 600 according to the sixth embodiment, since the threshold voltage of the MOSFET having the first portion 16a as its gate electrode is low, the channel resistance of the channel formed in the first region 36a is reduced. Therefore, the on-resistance of the MOSFET 600 is reduced.

On the other hand, since the threshold voltage of the MOSFET having the second portion 16b as its gate electrode is kept relatively high, the threshold voltage of the MOSFET 600 can be kept high.

For example, as shown in FIG. 28, since the position Py where the n-type impurity concentration is maximum faces the second portion 16b, the threshold voltage of the MOSFET having the second portion 16b as its gate electrode can be further increased.

From the viewpoint of reducing the on-resistance of the MOSFET 600, the difference between the work function of the first material and the work function of the second material is preferably equal to or more than 0.2 eV, more preferably equal to or more than 0.5 eV, and even more preferably equal to or more than 1.0 eV, for example.

As described above, according to the MOSFET 600 according to the sixth embodiment, it is possible to reduce the on-resistance.

### First Modification Example

A semiconductor device according to a first modification example of the sixth embodiment is different from the semiconductor device according to the sixth embodiment in that the second material is n-type polycrystalline silicon.

In a MOSFET according to the first modification example of the sixth embodiment, the second material contained in the second portion 16b of the gate electrode 16 is n-type polycrystalline silicon. Then, the first material contained in the first portion 16a of the gate electrode 16 is p-type polycrystalline silicon.

Since the n-type polycrystalline silicon is used as the second material, the work function of the second material is smaller than that when the second material is p-type polycrystalline silicon. Therefore, the difference between the work function of the first material and the work function of the second material can be made larger than in the MOSFET 600 according to the sixth embodiment.

According to the MOSFET according to the first modification example of the sixth embodiment, for example, it is possible to reduce the on-resistance more than in the MOSFET 600 according to the sixth embodiment.

### Second Modification Example

A semiconductor device according to a second modification example of the sixth embodiment is different from the semiconductor device according to the sixth embodiment in that the first region of the second semiconductor region is provided between the second region and the third semiconductor region.

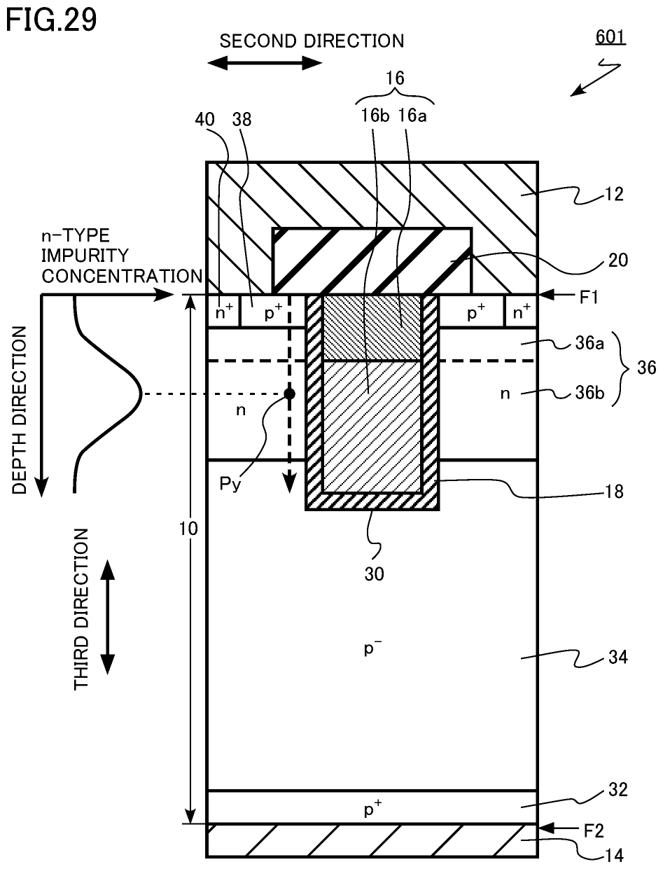

FIG. 29 is a schematic cross-sectional view of the semiconductor device according to the second modification example of the sixth embodiment. FIG. 29 is a diagram corresponding to FIG. 28 in the sixth embodiment. FIG. 29 shows the impurity concentration distribution in a part of the semiconductor layer. The semiconductor device according to the second modification example of the sixth embodiment is a MOSFET 601.

The n-type body region 36 includes a first region 36a and a second region 36b. The first region 36a is provided between the second region 36b and the source region 38.

The body region 36 contains n-type impurities. The n-type impurity is, for example, phosphorus (P) or arsenic (As). The n-type impurity concentration in the body region 36 is, for example, equal to or more than 1×10¹⁶ cm⁻³ and equal to or less than 1×10¹⁸ cm⁻³.

The n-type impurity concentration in the second region 36b is higher than the n-type impurity concentration in the first region 36a.

As shown in FIG. 29, the n-type impurity concentration in the depth direction in a region of the body region 36 along the gate insulating layer 18 is maximum at the position Py. The position Py is in the second region 36b. The n-type impurity concentration distribution in the depth direction in the region of the body region 36 along the gate insulating layer 18 has a maximum peak in the second region 36b.

The gate electrode 16 has a first portion 16a and a second portion 16b. The first portion 16a is provided on the first face F1 side with respect to the second portion 16b.

The second portion 16b is in contact with the first portion 16a. The first portion 16a and the second portion 16b are electrically connected to each other.

The first portion 16a faces the first region 36a of the body region 36 in the second direction. The second portion 16b faces the second region 36b of the body region 36 in the second direction.

The first portion 16a contains a first material. The second portion 16b contains a second material. The first portion 16a is formed of, for example, a first material. The second portion 16b is formed of, for example, a second material.

The work function of the first material is larger than the work function of the second material. The difference between the work function of the first material and the work function of the second material is, for example, equal to or more than 0.2 eV and equal to or less than 4.0 eV.

The first material and the second material are p-type polycrystalline silicon containing p-type impurities. The p-type impurity concentration of the first material is higher than the p-type impurity concentration of the second material.

As shown in FIG. 29, the position Py where the n-type impurity concentration in the depth direction in a region of the body region 36 along the gate insulating layer 18 is maximum faces the second portion 16b in the second direction, for example.

In the MOSFET 601 according to the second modification example of the sixth embodiment, the gate electrode 16 includes a first portion 16a and a second portion 16b. The work function of the first material contained in the first portion 16a is larger than the work function of the second material contained in the second portion 16b.

Since the work function of the first material is larger than the work function of the second material, the threshold voltage of the MOSFET formed by the first portion 16a, the gate insulating layer 18, and the first region 36a is lower than the threshold voltage of the MOSFET formed by the second portion 16b, the gate insulating layer 18, and the second region 36b. In other words, the threshold voltage of the MOSFET having the first portion 16a as its gate electrode is lower than the threshold voltage of the MOSFET having the second portion 16b as its gate electrode.

In the MOSFET 601 according to the second modification example of the sixth embodiment, since the threshold voltage of the MOSFET having the first portion 16a as its gate electrode is low, the channel resistance of the channel formed in the first region 36a is reduced. Therefore, the on-resistance of the MOSFET 601 is reduced.

On the other hand, since the threshold voltage of the MOSFET having the second portion 16b as its gate electrode is kept relatively high, the threshold voltage of the MOSFET 601 can be kept high.

For example, as shown in FIG. 29, since the position Py where the n-type impurity concentration is maximum faces the second portion 16b, the threshold voltage of the MOSFET having the second portion 16b as its gate electrode can be further increased.

From the viewpoint of reducing the on-resistance of the MOSFET 601, the difference between the work function of the first material and the work function of the second material is preferably equal to or more than 0.2 eV, more preferably equal to or more than 0.5 eV, and even more preferably equal to or more than 1.0 eV, for example.

According to the MOSFET 601 according to the second modification example of the sixth embodiment, it is possible to reduce the on-resistance as in the MOSFET 600 according to the sixth embodiment.

As described above, according to the sixth embodiment and its modification examples, it is possible to realize a semiconductor device that can reduce on-resistance.

Although the case where the semiconductor device is a MOSFET has been described as an example in the first to sixth embodiments, the semiconductor device may be an insulated gate bipolar transistor (IGBT).

In addition, while silicon has been described as an example of the material for the semiconductor layer in the first to sixth embodiments, other materials such as silicon carbide (SiC) and gallium nitride (GaN) can also be used for the semiconductor layer.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer having a first face and a second face opposite to the first face, the semiconductor layer including a first semiconductor region of a first conductive type, a second semiconductor region of a second conductive type provided between the first semiconductor region and the first face, and a third semiconductor region of the first conductive type provided between the second semiconductor region and the first face;
a first electrode provided on a first face side of the semiconductor layer and electrically connected to the third semiconductor region;
a second electrode provided on a second face side of the semiconductor layer;
a gate electrode provided in the semiconductor layer and facing the first semiconductor region, the second semiconductor region, and the third semiconductor region; and
a gate insulating layer provided between the gate electrode and the first semiconductor region, between the gate electrode and the second semiconductor region, and between the gate electrode and the third semiconductor region,
wherein the second semiconductor region includes a first region, a second region, and a third region, the first region is provided between the second region and the first semiconductor region, and the third region is provided between the second region and the third semiconductor region,
the gate electrode includes a first portion, a second portion, and a third portion, the first portion faces the first region, the second portion faces the second region, the third portion faces the third region, the first portion contains a first material, the second portion contains a second material, and the third portion contains a third material,
when the first conductive type is n-type and the second conductive type is p-type, a work function of the first material and a work function of the third material are smaller than a work function of the second material, and
when the first conductive type is p-type and the second conductive type is n-type, the work function of the first material and the work function of the third material are larger than the work function of the second material.

2. The semiconductor device according to claim 1,
wherein, in a cross section parallel to a direction from the first electrode to the second electrode and including the gate electrode and the semiconductor layer, a position where a second conductive type impurity concentration is maximum in a region of the second semiconductor region along the gate insulating layer faces the second portion.

3. The semiconductor device according to claim 1,
wherein the first material, the second material, and the third material are polycrystalline silicon.

4. The semiconductor device according to claim 3,
wherein the first material, the second material, and the third material have a same conductive type, and an impurity concentration of the first material and an impurity concentration of the third material are different from an impurity concentration of the second material.

5. The semiconductor device according to claim 3,
wherein a conductive type of the first material and a conductive type of the third material are different from a conductive type of the second material.

6. The semiconductor device according to claim 1,
wherein a first insulating film is provided between the first portion and the second portion, and a second insulating film is provided between the second portion and the third portion.

7. The semiconductor device according to claim 6,
wherein the first portion, the second portion, and the third portion are electrically connected to each other.

8. The semiconductor device according to claim 1,
wherein a length of the second portion in a direction from the first electrode to the second electrode is equal to or more than 20% and equal to or less than 70% of a length between the first semiconductor region and the third semiconductor region in the direction.

9. The semiconductor device according to claim 1,
wherein a difference between the work function of the first material and the work function of the second material is equal to or more than 0.2 eV, and
a difference between the work function of the third material and the work function of the second material is equal to or more than 0.2 eV.

10. The semiconductor device according to claim 1,
wherein the semiconductor layer is a silicon layer.

11. A semiconductor device, comprising:
a semiconductor layer having a first face and a second face opposite to the first face, the semiconductor layer including a first semiconductor region of n-type, a second semiconductor region of p-type provided between the first semiconductor region and the first face, and a third semiconductor region of n-type provided between the second semiconductor region and the first face;
a first electrode provided on a first face side of the semiconductor layer and electrically connected to the third semiconductor region;
a second electrode provided on a second face side of the semiconductor layer;
a gate electrode provided in the semiconductor layer and facing the first semiconductor region, the second semiconductor region, and the third semiconductor region; and
a gate insulating layer provided between the gate electrode and the first semiconductor region, between the gate electrode and the second semiconductor region, and between the gate electrode and the third semiconductor region,
wherein the second semiconductor region includes a first region and a second region, and the first region is provided between the second region and the first semiconductor region or between the second region and the third semiconductor region,
the gate electrode includes a first portion and a second portion, the first portion faces the first region, the second portion faces the second region, the first portion contains a first material, and the second portion contains a second material,
the first material is n-type polycrystalline silicon, and
a work function of the first material is smaller than a work function of the second material.

12. The semiconductor device according to claim 11,
wherein, in a cross section parallel to a direction from the first electrode to the second electrode and including the gate electrode and the semiconductor layer, a position where a p-type impurity concentration is maximum in a region of the second semiconductor region along the gate insulating layer faces the second portion.

13. The semiconductor device according to claim 11,
wherein the second material is polycrystalline silicon.

14. The semiconductor device according to claim 13,
wherein the second material is n-type polycrystalline silicon.

15. The semiconductor device according to claim 13,
wherein the second material is p-type polycrystalline silicon.

16. A semiconductor device, comprising:
a semiconductor layer having a first face and a second face opposite to the first face, the semiconductor layer including a first semiconductor region of p-type, a second semiconductor region of n-type provided between the first semiconductor region and the first face, and a third semiconductor region of p-type provided between the second semiconductor region and the first face;
a first electrode provided on a first face side of the semiconductor layer and electrically connected to the third semiconductor region;
a second electrode provided on a second face side of the semiconductor layer;
a gate electrode provided in the semiconductor layer and facing the first semiconductor region, the second semiconductor region, and the third semiconductor region; and
a gate insulating layer provided between the gate electrode and the first semiconductor region, between the gate electrode and the second semiconductor region, and between the gate electrode and the third semiconductor region,
wherein the second semiconductor region includes a first region and a second region, and the first region is provided between the second region and the first semiconductor region or between the second region and the third semiconductor region,
the gate electrode includes a first portion and a second portion, the first portion faces the first region, the second portion faces the second region, the first portion contains a first material, and the second portion contains a second material, and
a work function of the first material is larger than a work function of the second material.

17. The semiconductor device according to claim 16,
wherein, in a cross section parallel to a direction from the first electrode to the second electrode and including the gate electrode and the semiconductor layer, a position where an n-type impurity concentration is maximum in a region of the second semiconductor region along the gate insulating layer faces the second portion.

18. The semiconductor device according to claim 16,
wherein the first material and the second material are polycrystalline silicon.

19. The semiconductor device according to claim 18,
wherein the first material and the second material have a same conductive type, and an impurity concentration of the second material is different from an impurity concentration of the first material.

20. The semiconductor device according to claim 18,
wherein a conductive type of the second material is different from a conductive type of the first material.
